(19) United States
(12) Patent Application Publication
(10) Pub. No.: US 2024/0428060 A1
(43) Pub. Date: Dec. 26, 2024

(54) NEURAL NETWORK COMPUTATION CIRCUIT

(71) Applicant: Nuvoton Technology Corporation Japan, Kyoto (JP)

(72) Inventors: Reiji MOCHIDA, Osaka (JP); Takashi ONO, Osaka (JP); Kazuyuki KOUNO, Osaka (JP); Masayoshi NAKAYAMA, Kyoto (JP); Hitoshi SUWA, Osaka (JP); Junichi KATO, Kyoto (JP)

(21) Appl. No.: 18/824,460

(22) Filed: Sep. 4, 2024

Related U.S. Application Data
(63) Continuation of application No. PCT/JP2023/008647, filed on Mar. 7, 2023.

(30) Foreign Application Priority Data
Mar. 11, 2022 (JP) 2022-038226

(51) Int. Cl. G06N 3/063

(52) U.S. Cl. CPC G06N 3/063

(57) ABSTRACT

A neural network computation circuit holds a plurality of connection weight coefficients in one-to-one correspondence with a plurality of input data items, and outputs output data according to a result of a multiply-accumulate operation on the plurality of input data items and the plurality of connection weight coefficients in one-to-one correspondence, and includes at least two bits of semiconductor storage elements provided for each of the plurality of connection weight coefficients, the at least two bits of semiconductor storage elements including a first semiconductor storage element and a second semiconductor storage element that are provided for storing the connection weight coefficient. Each of the plurality of connection weight coefficients corresponds to a total current value that is a sum of a current value of current flowing through the first semiconductor storage element and a current value of current flowing through the second semiconductor storage element.

### CROSS REFERENCE TO RELATED APPLICATIONS

This is a continuation application of PCT International Application No. PCT/JP2023/008647 filed on Mar. 7, 2023, designating the United States of America, which is based on and claims priority of Japanese Patent Application No. 2022-038226 filed on Mar. 11, 2022. The entire disclosures of the above-identified applications, including the specifications, drawings and claims are incorporated herein by reference in their entirety.

### FIELD

The present disclosure relates to a neural network computation circuit that includes semiconductor storage elements.

### BACKGROUND

Along with development of information communication technology, the arrival of Internet of Things (IoT) technology with which various things are connected to the Internet has been attracting attention. With the IoT technology, performance of various electronic devices is expected to be improved by the devices being connected to the Internet, but nevertheless, as technology for achieving further improvement in performance, research and development of artificial intelligence (AI) technology that allows electronic devices to train themselves and make determinations have been actively conducted in recent years.

In the AI technology, neural network technology of technologically imitating brain information processing has been used, and research and development have been actively conducted for semiconductor integrated circuits that perform neural network computation at high speed with low power consumption.

Patent Literature (PTL) 1 discloses a conventional neural network computation circuit. A neural network computation circuit is configured using variable resistance nonvolatile memories (also simply referred to as “variable resistance elements” hereinafter) having settable analog resistance values (conductance). An analog resistance value corresponding to a connection weight coefficient (also simply referred to as a “weight coefficient” hereinafter) is stored in a nonvolatile memory element. An analog voltage having a value corresponding to an input (hereinafter, also referred to as “input data”) is applied to the nonvolatile memory element, and a value of analog current flowing through the nonvolatile memory element at this time is utilized. A multiply-accumulate operation performed in a neuron is performed by storing connection weight coefficients in nonvolatile memory elements as analog resistance values, applying analog voltages having values corresponding to inputs to the nonvolatile memory elements, and obtaining, as a result of the multiply-accumulate operation, an analog current value that is a sum of current values of current flowing through the nonvolatile memory elements. A neural network computation circuit that includes such nonvolatile memory elements can reduce power consumption as compared to a neural network computation circuit that includes a digital circuit, and process development, device development, and circuit development have been actively conducted in recent years for variable resistance nonvolatile memories having settable analog resistance values.

FIG. 8 illustrates calculations showing an operation principle of a conventional neural network computation circuit, and an operation of a computation unit.

Part (a) of FIG. 8 illustrates calculations showing an operation principle of a neural network computation circuit. As shown by Expression (1) in (a) of FIG. 8, computation by neuron 10 is performed by performing computation processing of activation function f on the result of a multiply-accumulate operation on input xi and connection weight coefficient wi. As shown by Expression (2) in (a) of FIG. 8, a multiply-accumulate operation is performed on input xi and current value Ii of current flowing through a variable resistance element, by replacing connection weight coefficient wi with current value Ii of current flowing through a variable resistance element (or stated differently, a memory cell).

Here, connection weight coefficient wi in neural network computation takes on both a positive value (≥0) and a negative value (<0), and when a product of input xi and connection weight coefficient wi in a multiply-accumulate operation has a positive value, addition is performed, whereas the product has a negative value, subtraction is performed. However, current value Ii of current flowing through a variable resistance element can take on a positive value only, and thus addition computation when a product of input xi and connection weight coefficient wi has a positive value can be performed by adding current value Ii, yet if subtraction computation when a product of input xi and connection weight coefficient wi has a negative value is to be performed using current value Ii, the subtraction computation needs to be performed ingeniously.

Part (b) of FIG. 8 illustrates operation of computation unit PUi that is a conventional neural network computation circuit. In the conventional neural network computation circuit, connection weight coefficient wi is stored in two variable resistance elements RP and RN, a resistance value set in variable resistance element RP is Rpi, a resistance value set in variable resistance element RN is Rni, a voltage applied to bit lines BL0 and BL1 is Vbl, and current values of current flowing through variable resistance elements RP and RN are Ipi and Ini. A positive result of the multiply-accumulate operation is added to current flowing through bit line BL0, and a negative result of the multiply-accumulate operation is added to current flowing through bit line BL1, which are features. In order to cause current to flow as stated above, resistance values Rpi and Rni (or stated differently, current values Ipi and Ini) of variable resistance elements RP and RN are set. Such computation units PUi, the number of which is the same as the number of inputs x0 to xn (corresponding connection weight coefficients w0 to wn) as illustrated in (a) of FIG. 8, are connected in parallel to bit lines BL0 and BL1, and thus a positive result of the multiply-accumulate operation of neuron 10 can be obtained as a current value of current flowing through bit line BL0 and a negative result of the multiply-accumulate operation can be obtained as a current value of current flowing through bit line BL1.

Expression (3), Expression (4), and Expression (5) in (a) of FIG. 8 show calculations of operations described above. Specifically, by appropriately writing resistance values Rpi and Rni corresponding to connection weight coefficients wi to variable resistance elements RP and RN in computation unit PUi, current values corresponding to a positive result and a negative result of a multiply-accumulate operation can be obtained for bit lines BL0 and BL1. Neural network computation can be performed by computing activation function f using such current values as inputs.

### CITATION LIST

### Patent Literature

PTL 1: International Publication No. WO2019/049741

### SUMMARY

### Technical Problem

However, the conventional neural network computation circuit described above has problems as follows. Stated differently, the range of an analog resistance value that can be set to a nonvolatile memory element that stores therein a connection weight coefficient is limited, and thus a large connection weight coefficient for improving performance of neural network computation cannot be stored, which is a problem. Furthermore, plural analog voltages having values corresponding to plural inputs are applied to plural nonvolatile memory elements, and an analog current value that is a sum of current values of current flowing through plural nonvolatile memory elements is obtained as a result of a multiply-accumulate operation. Hence, the analog current that is the sum is saturated by being influenced by parasitic resistance or a control circuit, and thus a multiply-accumulate operation cannot be accurately performed, which is also a problem. Moreover, in order to improve reliability of an analog resistance value set in a nonvolatile memory, when an analog resistance value is written, it is effective to use a write algorithm according to the analog resistance value to be set, but the analog resistance value is to be set in the same nonvolatile memory region, and thus a write algorithm according to an analog resistance value that is set cannot be used, which is also a problem. Note that a write algorithm defines how the following are combined and written: an absolute value of a voltage pulse or a current pulse applied when writing is performed on a memory element that is a write target, a pulse duration thereof, and a verify operation for checking that a predetermined resistance value has been written, for instance.

In particular, in a variable resistance nonvolatile memory, a filament that serves as a current path is formed in each nonvolatile memory element in an inspection process. In order to improve reliability of an analog resistance value set in a nonvolatile memory, this filament is to have a size according to an absolute value of an analog resistance value that is set, yet the analog resistance value that is set differs for a neural network. Thus, when the analog resistance value is assumed to be rewritten to another neural network, it is impossible to form a filament having an optimal size for each analog resistance value that is set, which is also a problem.

The present disclosure has been conceived in view of the above problem, and is to provide a neural network computation circuit that achieves at least one of improvement in performance of neural network computation or improvement in reliability of a semiconductor storage element that stores therein a connection weight coefficient.

### Solution to Problem

A neural network computation circuit according to an aspect of the present disclosure is a neural network computation circuit that holds a plurality of connection weight coefficients in one-to-one correspondence with a plurality of input data items each of which selectively takes on a first logical value or a second logical value, and outputs output data having the first logical value or the second logical value according to a result of a multiply-accumulate operation on the plurality of input data items and the plurality of connection weight coefficients in one-to-one correspondence, the neural network computation circuit including: at least two bits of semiconductor storage elements provided for each of the plurality of connection weight coefficients, the at least two bits of semiconductor storage elements including a first semiconductor storage element and a second semiconductor storage element that are provided for storing the connection weight coefficient. Each of the plurality of connection weight coefficients corresponds to a total current value that is a sum of a current value of current flowing through the first semiconductor storage element and a current value of current flowing through the second semiconductor storage element.

### Advantageous Effects

A neural network computation circuit according to the present disclosure can achieve at least one of improvement in performance of neural network computation or improvement in reliability of a semiconductor storage element that stores therein a connection weight coefficient.

### BRIEF DESCRIPTION OF DRAWINGS

These and other advantages and features will become apparent from the following description thereof taken in conjunction with the accompanying Drawings, by way of non-limiting examples of embodiments disclosed herein.

FIG. 1 illustrates a detailed configuration of a neural network computation circuit according to an embodiment.

FIG. 2 illustrates a configuration of a deep neural network.

FIG. 3 illustrates calculations by a neuron in neural network computation.

FIG. 4 illustrates calculations when computation of a biased coefficient is assigned to inputs and connection weight coefficients in neuron calculation in neural network computation.

FIG. 5 illustrates an activation function of a neuron in neural network computation according to the embodiment.

FIG. 6 is a block diagram illustrating the entire configuration of a neural network computation circuit according to the embodiment.

FIG. 7 illustrates a circuit diagram of a memory cell that is a nonvolatile semiconductor storage element according to the embodiment, a cross sectional view thereof, and applied voltages in operations thereof.

FIG. 8 illustrates calculations showing an operation principle of a neural network computation circuit, and an operation of a computation unit.

FIG. 9 illustrates calculations showing an operation principle of a neural network computation circuit and an operation of a computation unit, according to the embodiment.

FIG. 10 illustrates a detailed operation of the computation unit according to the embodiment.

FIG. 11 is a drawing for explaining a method for writing, by using storing method 1, a connection weight coefficient to a variable resistance element in the computation unit according to the embodiment.

FIG. 12 is a drawing for explaining a method for writing, by using storing method 2, a connection weight coefficient to a variable resistance element in the computation unit according to the embodiment.

FIG. 13 is a drawing for explaining a method for writing, by using storing method 3, a connection weight coefficient to a variable resistance element in the computation unit according to the embodiment.

FIG. 14 is a drawing for explaining a configuration of a neural network computation circuit according to a specific example.

FIG. 15 illustrates specific examples of current values according to storing method 1.

FIG. 16 illustrates specific examples of current values according to storing method 2.

FIG. 17 illustrates a current value (vertical axis) obtained as a result of a multiply-accumulate operation relative to an ideal value (horizontal axis) of a result of the multiply-accumulate operation, by comparing conventional technology and the present embodiment.

FIG. 18 illustrates specific examples of current values according to storing method 3.

FIG. 19 illustrates a detailed configuration of a neural network computation circuit according to a variation of the embodiment.

### DESCRIPTION OF EMBODIMENTS

In the following, embodiments of a neural network computation circuit according to the present disclosure are to be described with reference to the drawings. Note that the embodiments described below each show a specific example of the present disclosure. The numerical values, shapes, materials, elements, the arrangement and connection of the elements, steps, and the processing order of the steps, for instance, shown in the following embodiments are mere examples, and therefore are not intended to limit the scope of the present disclosure. Furthermore, the drawings do not necessarily provide strictly accurate illustration. In the drawings, the same numeral is given to substantially the same configuration, and a redundant description thereof may be omitted or simplified. Moreover, “being connected” means electrical connection, and also includes not only the case where two circuit elements are directly connected, but also the case where two circuit elements are indirectly connected in a state in which another circuit element is provided between the two circuit elements.

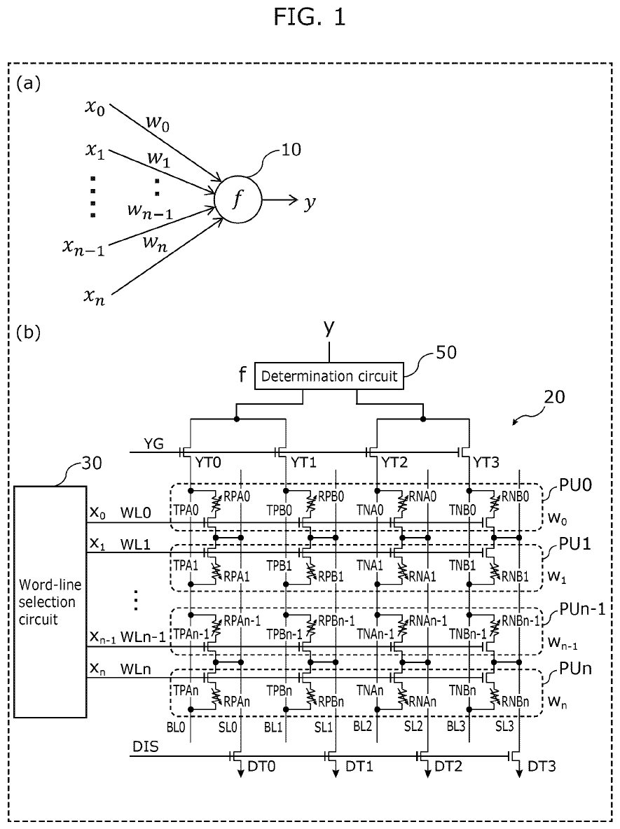

FIG. 1 illustrates a detailed configuration of a neural network computation circuit according to an embodiment. More specifically, (a) of FIG. 1 illustrates neuron 10 used in neural network computation performed by a neural network computation circuit according to the embodiment. Part (b) of FIG. 1 illustrates a detailed circuit configuration in the case where the neural network computation circuit according to the present disclosure performs computation processing performed by the neuron in (a) of FIG. 1, and is a representative drawing illustrating features of the neural network computation circuit according to the present disclosure. Parts (a) and (b) of FIG. 1 are to be described later in detail.

### <Neural Network Computation>

First, basic theory of neural network computation is to be described.

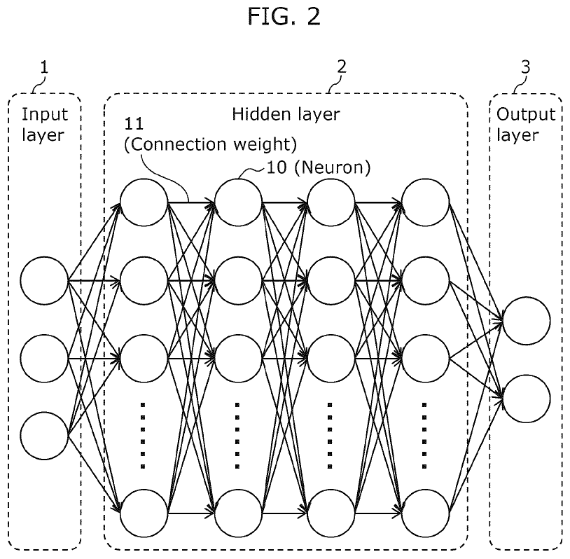

FIG. 2 illustrates a configuration of a deep neural network. The neural network includes input layer 1 to which input data is input, hidden layer 2 (which may also be referred to as an intermediate layer) that receives input data from input layer 1 and performs computation processing thereon, and output layer 3 that receives output data from hidden layer 2 and performs computation processing thereon. In each of input layer 1, hidden layer 2, or output layer 3, a large number of basic elements of a neural network referred to as neurons 10 are present, and neurons 10 are connected via connection weights 11. Connection weights 11 have different connection weight coefficients and connect neurons. Plural input data items are input to neuron 10, and neuron 10 performs a multiply-accumulate operation on the input data items and corresponding connection weight coefficients, and outputs the result as output data. Here, hidden layer 2 is configured by connecting neurons in plural stages (four stages in FIG. 2), and a neural network as illustrated in FIG. 2 is referred to as a deep neural network from the meaning that a deep neural network is formed.

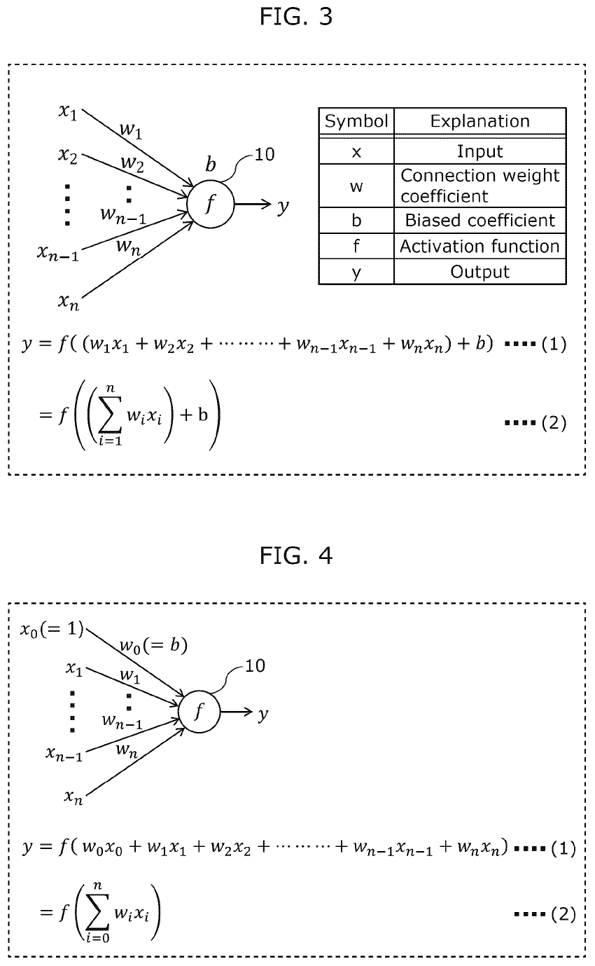

FIG. 3 illustrates calculations by a neuron in neural network computation. Here, Expression (1) and Expression (2) in FIG. 3 show mathematical expressions calculated by neuron 10. N inputs x1 to xn are connected to neuron 10 with connection weights having connection weight coefficients w1 to wn, and neuron 10 performs a multiply-accumulate operation on inputs x1 to xn and connection weight coefficients w1 to wn. Neuron 10 has biased coefficient b, and biased coefficient b is added to the result of the multiply-accumulate operation on inputs x1 to xn and connection weight coefficients w1 to wn. Neuron 10 has activation function f, and performs computation processing of the activation function on the result of adding biased coefficient b to the result of the multiply-accumulate operation on inputs x1 to xn and connection weight coefficients w1 to wn and outputs output y.

FIG. 4 illustrates calculations when computation of biased coefficient b is assigned to input x0 and connection weight coefficient w0 in neuron calculation in neural network computation. Expression (1) and Expression (2) in FIG. 4 show mathematical expressions calculated by neuron 10. In FIG. 3 described above, neuron 10 performs a multiply-accumulate operation on inputs x1 to xn and connection weight coefficients w1 to wn and addition computation of biased coefficient b. Yet nevertheless, as illustrated in FIG. 4, assuming that the addition computation of biased coefficient b is performed with the multiplication of input x0=1 and connection weight coefficient w0=b, neuron 10 can be interpreted as a neuron in which n+1 inputs x0 to xn are connected with connection weights having connection weight coefficients w0 to wn. As illustrated in Expression (1) and Expression (2) in FIG. 4, calculation by neuron 10 can be simply expressed by only a multiply-accumulate operation on inputs x0 to xn and connection weight coefficients w0 to wn. In the present embodiment, as illustrated in FIG. 4, the addition computation of biased coefficient b is expressed as input x0=1 and connection weight coefficient w0=b.

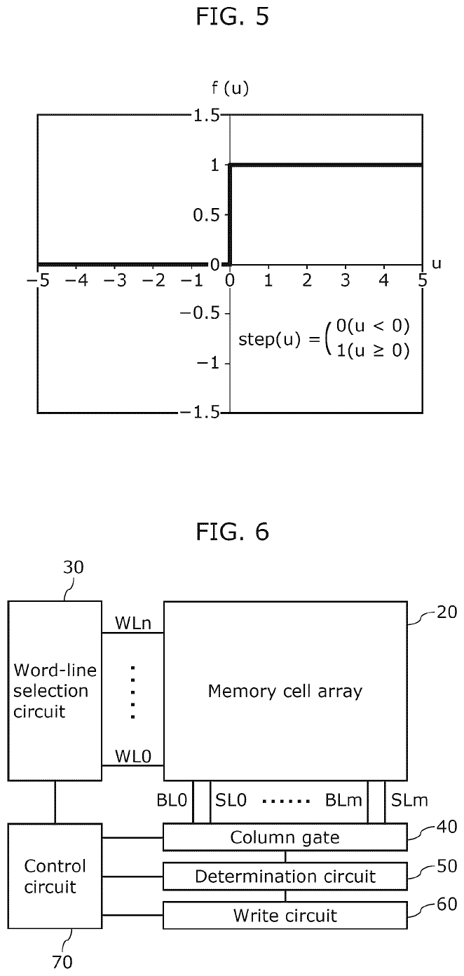

FIG. 5 illustrates activation function f of a neuron in neural network computation. The horizontal axis represents input u of activation function f, whereas the vertical axis represents output f(u) of activation function f. In the embodiment of the neural network computation circuit of the present disclosure, a step function is used as activation function f. Note that although a step function is used as an activation function in the present embodiment, a sigmoid function, for instance, is used as another activation function used in neural network computation, and thus the function used by the neural network computation circuit of the present disclosure is not limited to a step function. As illustrated in FIG. 5, a step function outputs output f(u)=0 when input u has a negative value (<0), and outputs output f(u)=1 when input u has a positive value (≥0). In neuron 10 in FIG. 4 described above, in the case where activation function f that is a step function is used, when a result of a multiply-accumulate operation on inputs x0 to xn and connection weight coefficients w0 to wn is a negative value, output y=0 is output, and when the result of the multiply-accumulate operation is a positive value, output y=1 is output.

### <Entire Configuration of Neural Network Computation Circuit>

FIG. 6 is a block diagram illustrating the entire configuration of a neural network computation circuit according to the embodiment. The neural network computation circuit according to the present disclosure includes memory cell array 20, word-line selection circuit 30, column gate 40, determination circuit 50, write circuit 60, and control circuit 70.

Memory cell array 20 includes nonvolatile semiconductor storage elements disposed in a matrix, and connection weight coefficients used in neural network computation are stored in the nonvolatile semiconductor storage elements. Memory cell array 20 includes a plurality of word lines WL0 to WLn, a plurality of bit lines BL0 to BLm, and a plurality of source lines SL0 to SLm.

Word-line selection circuit 30 drives word lines WL0 to WLn in memory cell array 20. Word-line selection circuit 30 places a word line in a selected state or a non-selected state, according to an input of a neuron in neural network computation.

Column gate 40 is connected to bit lines BL0 to BLm and source lines SL0 to SLm, selects one or more bit lines and one or more source lines from bit lines BL0 to BLm and source lines SL0 to SLm, and connects the selected bit line(s) and the selected source line(s) to determination circuit 50 and write circuit 60.

Determination circuit 50 is connected to bit lines BL0 to BLm and source lines SL0 to SLm via column gate 40. Determination circuit 50 detects a value of current flowing through a bit line or a source line, and outputs output data. Determination circuit 50 reads out data stored in a memory cell in memory cell array 20 and outputs output data from a neuron in neural network computation.

Write circuit 60 is connected to bit lines BL0 to BLm and source lines SL0 to SLm via column gate 40, and applies a rewrite voltage to a nonvolatile semiconductor storage element in memory cell array 20.

Control circuit 70 controls operation of memory cell array 20, word-line selection circuit 30, column gate 40, determination circuit 50, and write circuit 60, and includes, for instance, a processor that controls a readout operation and a write operation on a memory cell in memory cell array 20 and a neural network computation operation.

### <Configuration of Nonvolatile Semiconductor Storage Element>

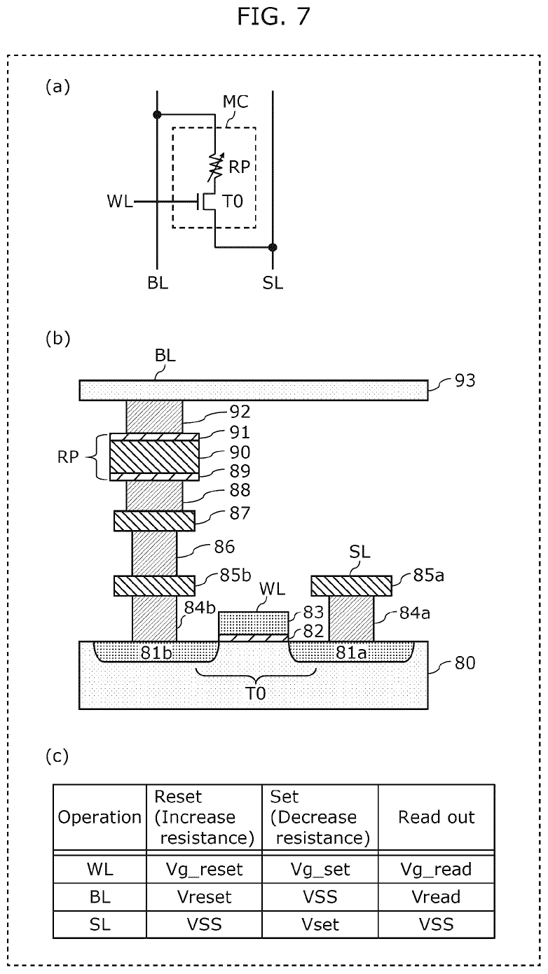

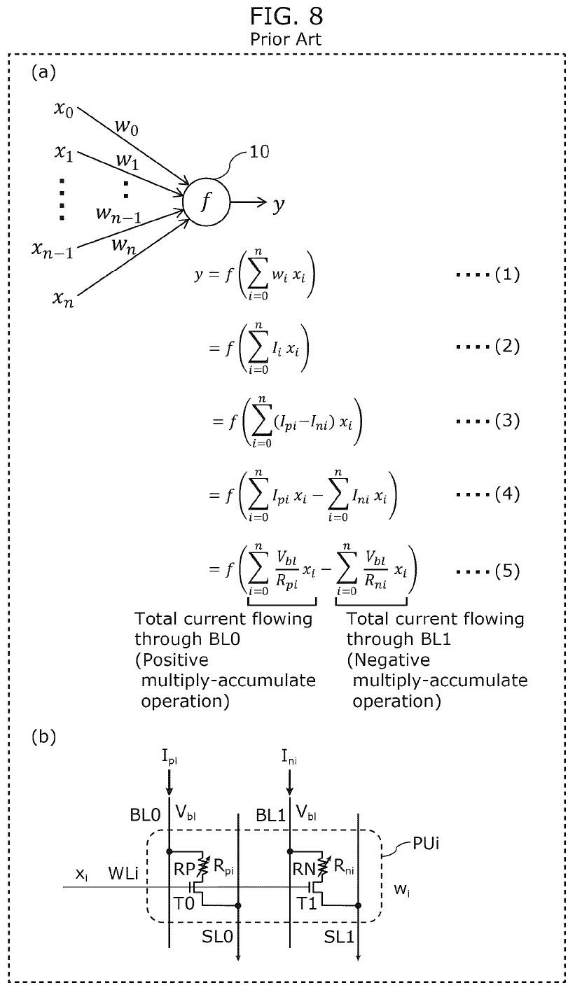

FIG. 7 illustrates a circuit t diagram of a nonvolatile semiconductor storage element according to the embodiment, a cross sectional view thereof, and applied voltages in operations thereof.

Part (a) of FIG. 7 is a circuit diagram of memory cell MC that is a nonvolatile semiconductor storage element included in memory cell array 20 in FIG. 6. Memory cell MC includes variable resistance element RP and cell transistor T0 connected in series, and is a “1T1R” memory cell that includes one cell transistor T0 and one variable resistance element RP. Variable resistance element RP is a nonvolatile semiconductor storage element referred to as a resistive random access memory (ReRAM). Word line WL in memory cell MC is connected to a gate terminal of cell transistor T0, bit line BL is connected to variable resistance element RP, and source line SL is connected to a source terminal of cell transistor T0.

Part (b) of FIG. 7 is a cross sectional view of memory cell MC in (a) of FIG. 7. Diffusion regions 81a and 81b are provided in semiconductor substrate 80, and diffusion region 81a functions as a source terminal of cell transistor T0, whereas diffusion region 81b functions as a drain terminal of cell transistor T0. A portion between diffusion regions 81a and 81b functions as a channel region of cell transistor T0, oxide film 82 and gate electrode 83 made of polysilicon are provided above the channel region and function as cell transistor T0. Diffusion region 81a that is a source terminal of cell transistor T0 is connected to source line SL that is first wiring layer 85a through via 84a. Diffusion region 81b that is a drain terminal of cell transistor T0 is connected to first wiring layer 85b through via 84b. Furthermore, first wiring layer 85b is connected to second wiring layer 87 through via 86, whereas second wiring layer 87 is connected to variable resistance element RP through via 88. Variable resistance element RP includes lower electrode 89, variable resistance layer 90, and upper electrode 91. Variable resistance element RP is connected to bit line BL that is third wiring layer 93 through via 92.

Part (c) of FIG. 7 illustrates applied voltages in operation modes of memory cell MC in (a) of FIG. 7.

In a resetting operation (to increase resistance), a voltage of Vg_reset (2 V, for example) is applied to word line WL to place cell transistor T0 in a selected stated, a voltage of Vreset (2.0 V, for example) is applied to bit line BL, and ground voltage VSS (0 V) is applied to source line SL. Accordingly, a positive voltage is applied to the upper electrode of variable resistance element RP, and the resistance of variable resistance element RP is changed to a high resistance state.

In a setting operation (to decrease resistance), a voltage of Vg_set (2.0 V, for example) is applied to word line WL to place cell transistor T0 in a selected stated, ground voltage VSS (0 V) is applied to bit line BL, and a voltage of Vset (2.0 V, for example) is applied to source line SL. Accordingly, a positive voltage is applied to the lower electrode of variable resistance element RP, and the resistance of variable resistance element RP is changed to a low resistance state.

In a reading operation, a voltage of Vg_read (1.1 V, for example) is applied to word line WL to place cell transistor T0 in a selected stated, a voltage of Vread (0.4 V, for example) is applied to bit line BL, and ground voltage VSS (0 V) is applied to source line SL. Accordingly, when variable resistance element RP is in a high resistance state (reset state), small memory cell current flows through variable resistance element RP, whereas when variable resistance element RP is in a low resistance state (set state), large memory cell current flows through variable resistance element RP. The determination circuit determines a difference between the current values, to perform an operation of reading out data stored in memory cell MC.

When memory cell MC is used as a semiconductor memory that stores data 0 or data 1, the resistance value of variable resistance element RP can be placed in only two resistance states (digital), that is, the high resistance state (data 0) and the low resistance state (data 1). When memory cell MC is used as a neural network computation circuit according to the present disclosure, the resistance value of variable resistance element RP is set to a multi-level (that is, analog) value and used.

### <Detailed Configuration of Neural Network Computation Circuit>

FIG. 1 illustrates a detailed configuration of a neural network computation circuit according to an embodiment.

Part (a) of FIG. 1 illustrates neuron 10 used in neural network computation performed by a neural network computation circuit according to the embodiment, and is the same as FIG. 4. N+1 inputs x0 to xn are input to neuron 10 with connection weight coefficients w0 to wn. Inputs x0 to xn may take on either value of data 0 or data 1, and connection weight coefficients w0 to wn may take on a multi-level (analog) value. Computation of activation function f that is the step function illustrated in FIG. 5 is performed on a result of a multiply-accumulate operation on inputs x0 to xn and connection weight coefficients w0 to wn, and output y is output. Note that data 0 is an example that is one of a first logical value or a second logical value that input data can selectively take on, and data 1 is an example that is the remaining one of the first logical value or the second logical value.

Part (b) of FIG. 1 illustrates a detailed configuration of a circuit that performs computation processing of neuron 10 in (a) of FIG. 1. Memory cell array 20 includes word lines WL0 to WLn, bit lines BL0, BL1, BL2, and BL3, and source lines SL0, SL1, SL2, and SL3.

Word lines WL0 to WLn are in one-to-one correspondence with inputs x0 to xn of neuron 10. Input x0 is in correspondence with word line WL0, input x1 is in correspondence with word line WL1, input xn−1 is in correspondence with word line WLn−1, and input xn is in correspondence with word line WLn. Word-line selection circuit 30 places word lines WL0 to WLn in a selected state or a non-selected state, according to inputs x0 to xn. For example, when input is data 0, a word line is placed in a non-selected state, whereas when input is data 1, a word line is placed in a selected state. In neural network computation, inputs x0 to xn can each take on a value of data 0 or data 1, and thus when inputs x0 to xn include plural data 1 items, word-line selection circuit 30 selects plural word lines at the same time.

Computation units PU0 to PUn each including memory cells are in one-to-one correspondence with connection weight coefficients w0 to wn of neuron 10. Connection weight coefficient w0 is in correspondence with computation unit PU0, connection weight coefficient w1 is in correspondence with computation unit PU1, connection weight coefficient wn−1 is in correspondence with computation unit PUn−1, and connection weight coefficient wn is in correspondence with computation unit PUn.

Computation unit PU0 includes: a first memory cell that includes variable resistance element RPA0 that is an example of a first semiconductor storage element and cell transistor TPA0 that is an example of a first cell transistor, which are connected in series; a second memory cell that includes variable resistance element RPB0 that is an example of a second semiconductor storage element and cell transistor TPB0 that is an example of a second cell transistor, which are connected in series; a third memory cell that includes variable resistance element RNA0 that is an example of a third semiconductor storage element and cell transistor TNA0 that is an example of a third cell transistor, which are connected in series; and a fourth memory cell that includes variable resistance element RNB0 that is an example of a fourth semiconductor storage element and cell transistor TNB0 that is an example of a fourth cell transistor, which are connected in series. Thus, one computation unit includes four memory cells.

The first semiconductor storage element and the second semiconductor storage element are used to store a positive connection weight coefficient included in one connection weight coefficient. The positive connection weight coefficient corresponds to a total current value that is a sum of a current value of current flowing through the first semiconductor storage element and a current value of current flowing through the second semiconductor storage element. In contrast, the third semiconductor storage element and the fourth semiconductor storage element are used to store a negative connection weight coefficient included in the one connection weight coefficient. The negative connection weight coefficient corresponds to a total current value that is a sum of a current value of current flowing through the third semiconductor storage element and a current value of current flowing through the fourth semiconductor storage element.

Computation unit PU0 is connected to word line WL0 that is an example of a first word line, bit line BL0 that is an example of a first data line, bit line BL1 that is an example of a third data line, bit line BL2 that is an example of a fifth data line, bit line BL3 that is an example of a seventh data line, source line SL0 that is an example of a second data line, source line SL1 that is an example of a fourth data line, source line SL2 that is an example of a sixth data line, and source line SL3 that is an example of an eighth data line. Word line WL0 is connected to the gate terminals of cell transistors TPA0, TPB0, TNA0, and TNB0, bit line BL0 is connected to variable resistance element RPA0, bit line BL1 is connected to variable resistance element RPB0, source line SL0 is connected to the source terminal of cell transistor TPA0, source line SL1 is connected to the source terminal of cell transistor TPB0, bit line BL2 is connected to variable resistance element RNA0, bit line BL3 is connected to variable resistance element RNB0, source line SL2 is connected to the source terminal of cell transistor TNA0, and source line SL3 is connected to the source terminal of cell transistor TNB0.

Input x0 is input through word line WL0 of computation unit PU0, and connection weight coefficient w0 is stored as a resistance value (stated differently, conductance) in four variable resistance elements RPA0, RPB0, RNA0, and RNB0 of computation unit PU0. A configuration of computation units PU1, PUn−1, and PUn is equivalent to the configuration of computation unit PU0, and thus detailed description thereof is omitted. Here, inputs x0 to xn are input through word lines WL0 to WLn connected to computation units PU0 to PUn, respectively, connection weight coefficients w0 to wn are stored as resistance values (stated differently, conductance) in variable resistance elements RPA0 to RPAn, RPB0 to RPBn, RNA0 to RNAn, and RNB0 to RNBn of computation units PU0 to PUn.

Bit lines BL0 and BL1 are connected to determination circuit 50 via column gate transistors YT0 and YT1, respectively. Bit lines BL2 and BL3 are connected to determination circuit 50 via column gate transistors YT2 and YT3, respectively. The gate terminals of column gate transistors YT0, YT1, YT2, and YT3 are connected to column-gate control signal line YG, and when column-gate control signal line YG is activated, bit lines BL0, BL1, BL2, and BL3 are connected to determination circuit 50.

Source lines SL0, SL1, SL2, and SL3 are connected to the ground voltage supply via discharge transistors DT0, DT1, DT2, and DT3, respectively. The gate terminals of discharge transistors DT0, DT1, DT2, and DT3 are connected to discharge control signal line DIS, and when discharge control signal line DIS is activated, source lines SL0, SL1, SL2, and SL3 are set to the ground voltage.

When a neural network computation operation is performed, column-gate control signal line YG and discharge control signal line DIS are activated, to connect bit lines BL0, BL1, BL2, and BL3 to determination circuit 50, and source lines SL0, SL1, SL2, and SL3 to the ground voltage supply.

Determination circuit 50 detects a sum of current values of current flowing through bit lines BL0 and BL1 connected via column gate transistors YT0 and YT1 (the value of the sum obtained is also referred to as a “first total current value”) and a sum of current values of current flowing through bit line BL2 and bit line BL3 connected via column gate transistors YT2 and YT3 (the value of the sum obtained is also referred to as a “third total current value”), compares the first total current value and the third total current value that are detected, and outputs output y. Output y may take on a value that is either data 0 or data 1.

More specifically, determination circuit 50 outputs output y of data 0 when the first total current value is smaller than the third total current value, and outputs output y of data 1 when the first total current value is greater than the third total current value. Thus, determination circuit 50 determines a magnitude relation between the first total current value and the third total current value, and outputs output y.

Note that instead of determining the magnitude relation between the first total current value and the third total current value, determination circuit 50 may detect a sum of current values of current flowing through source line SL0 and source line SL1 (the value of the sum obtained is also referred to as a “second total current value”), and a sum of the current values of current flowing through source line SL2 and source line SL3 (the value of the sum obtained is also referred to as a “fourth total current value”), compare the second total current value and the fourth total current value that are detected, and output output y.

This is because current flowing through bit line BL0 (more accurately, column gate transistor YT0) and current flowing through source line SL0 (more accurately, discharge transistor DT0) have the same current value, current flowing through bit line BL1 (more accurately, column gate transistor YT1) and current flowing through source line SL1 (more accurately, discharge transistor DT1) have the same current value, current flowing through bit line BL2 (more accurately, column gate transistor YT2) and current flowing through source line SL2 (more accurately, discharge transistor DT2) have the same current value, and current flowing through bit line BL3 (more accurately, column gate transistor YT3) and current flowing through source line SL3 (more accurately, discharge transistor DT3) have the same current value.

Thus, determination circuit 50 may determine the magnitude relation between the first or second total current value and the third or fourth total current value, and output data having the first or second logical value.

When a conversion circuit such as a shunt resistor, which converts the first to fourth total current values into voltages, is included in the neural network computation circuit, determination circuit 50 may make similar determinations by using first to fourth voltage values corresponding to the first to fourth total current values.

As described above, in the present embodiment, the first semiconductor storage element and the second semiconductor storage element hold a positive-value connection weight coefficient that causes the first total current value or the second total current value to be a current value corresponding to a result of a multiply-accumulate operation on plural input data items corresponding to connection weight coefficients having positive values and the corresponding connection weight coefficients having the positive values. On the other hand, the third semiconductor storage element and the fourth semiconductor storage element hold a negative-value connection weight coefficient that causes the third total current value or the fourth total current value to be a current value corresponding to a result of a multiply-accumulate operation on plural input data items corresponding to connection weight coefficients having negative values and the corresponding connection weight coefficients having the negative values.

Note that with regard to the computation units in the present embodiment, in order to simplify the description, an example in which a positive weight coefficient is included in two memory cells, and a negative weight coefficient is included in two memory cells has been described, yet a positive weight coefficient and a negative weight coefficient can each be included in one memory cell to n memory cells, and thus are not limited to be each included in two memory cells. Thus, the computation units according to the present disclosure have a feature that at least one of a positive weight coefficient or a negative weight coefficient is included in two or more memory cells. Furthermore, each of the computation units according to the present disclosure may not necessarily include both of a positive weight coefficient and a negative weight coefficient, and may include one weight coefficient included in at least two memory cells (that is, a weight coefficient without a sign).

An operation principle and an operation method of the neural network computation circuit configured as above and a method of storing connection weight coefficients into variable resistance elements are to be described in detail in the following.

### <Operation Principle of Neural Network Computation Circuit>

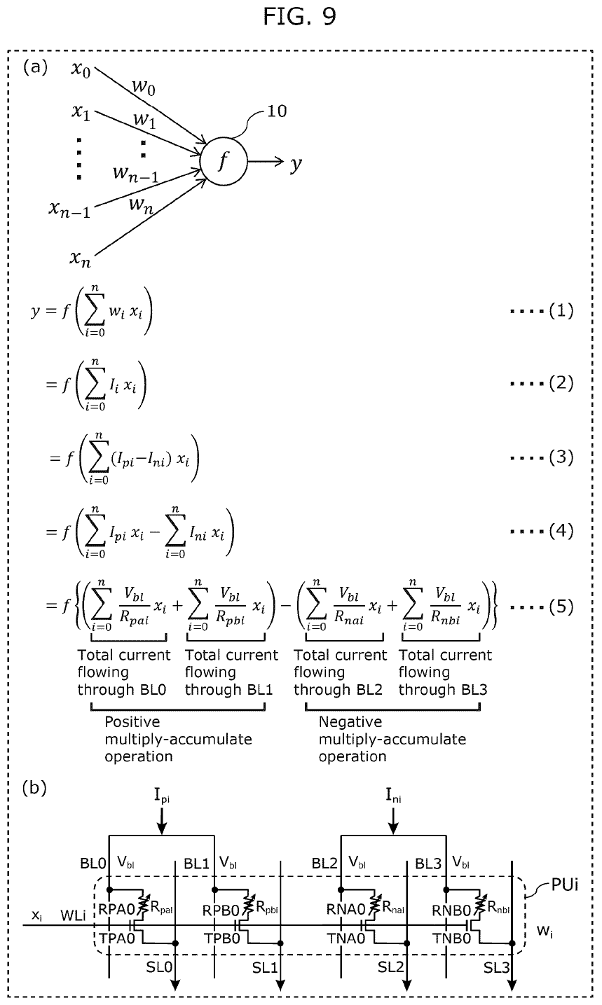

FIG. 9 illustrates calculations showing an operation principle of a neural network computation circuit and an operation of a computation unit, according to the embodiment.

Part (a) of FIG. 9 illustrates calculations showing an operation principle of a neural network computation circuit according to the embodiment. As shown by Expression (1) in (a) of FIG. 9, computation by neuron 10 is performed by performing computation processing of activation function f that is a step function on the result of a multiply-accumulate operation on input xi and connection weight coefficient wi. Neural network computation according to the present disclosure has a feature that as shown by Expression (2) in (a) of FIG. 9, a multiply-accumulate operation is performed on input xi and current value Ii of current flowing through a variable resistance element, by replacing connection weight coefficient wi with current value Ii of current flowing through a variable resistance element (or stated differently, a memory cell).

Here, connection weight coefficient wi in neural network computation can take on both a positive value (≥0) and a negative value (<0), and when a product of input xi and connection weight coefficient wi in a multiply-accumulate operation has a positive value, addition is performed, whereas when the product has a negative value, subtraction is performed. However, current value Ii of current flowing through a variable resistance element can take on a positive value only, and thus addition computation when a product of input xi and connection weight coefficient wi has a positive value can be performed by adding current value Ii, yet if subtraction computation when a product of input xi and connection weight coefficient wi has a negative value is to be performed using current value Ii, the subtraction computation needs to be performed ingeniously.

Part (b) of FIG. 9 illustrates operation of computation unit PUi according to the embodiment. A configuration of computation unit PUi is as described with reference to (a) and (b) of FIG. 1, and thus detailed description is omitted. A neural network computation circuit according to the present disclosure has a feature that a connection weight coefficient is stored in four variable resistance elements RPA0, RPB0, RNA0, and RNB0. A resistance value set in variable resistance element RPA0 is Rpai, a resistance value set in variable resistance element RPB0 is Rpbi, a resistance value set in variable resistance element RNA0 is Rnai, and a resistance value set in variable resistance element RNB0 is Rnbi. A voltage applied to bit lines BL0, BL1, BL2, and BL3 is Vbl. A sum of current values of current flowing through variable resistance elements RPA0 and RPB0 is Ipi, and a sum of current values of current flowing through variable resistance elements RNA0 and RNB0 is Ini.

The neural network computation circuit according to the present disclosure has features that a positive result of a multiply-accumulate operation is added to current flowing through bit lines BL0 and BL1, and a negative result of a multiply-accumulate operation is added to current flowing through bit lines BL2 and BL3. In order to cause current to flow as stated above, resistance values Rpai, Rpbi, Rnai, and Rnbi (or stated differently, current values Ipi and Ini) of variable resistance elements RPA0, RPB0, RNA0, and RNB0 are set. Such computation units PUi, the number of which is the same as the number of inputs x0 to xn (corresponding connection weight coefficients w0 to wn), are connected in parallel to bit lines BL0, BL1, BL2, and BL3 as illustrated in (b) of FIG. 1, and thus a positive result of a multiply-accumulate operation of neuron 10 can be obtained as a first total current value of current flowing through bit lines BL0 and BL1, and a negative result of a multiply-accumulate operation can be obtained as a third total current value of current flowing through bit lines BL2 and BL3.

Expression (3), Expression (4), and Expression (5) in (a) of FIG. 9 show calculations of operations described above. Thus, by appropriately writing resistance values Rpai, Rpbi, Rnai, and Rnbi corresponding to connection weight coefficient wi to variable resistance elements RPA0, RPB0, RNA0, and RNB0 in computation unit PUi, a current value corresponding to a positive result of a multiply-accumulate operation can be obtained for bit lines BL0 and BL1, and a current value corresponding to a negative result of a multiply-accumulate operation can be obtained for bit lines BL2 and BL3.

In Expression (5) in (a) of FIG. 9, activation function f is a step function (data 0 is output when an input has a negative value (<0), whereas data 1 is output when an input has a positive value (≥0)). Hence, when a sum (that is, the first total current value) of current values of current flowing through bit lines BL0 and BL1, which is a positive result of a multiply-accumulate operation, is smaller than a sum (the third total current value) of current values of current flowing through bit lines BL2 and BL3, which is a negative result of a multiply-accumulate operation, or stated differently, when all the results of a multiply-accumulate operation are negative values, data 0 is output, whereas when a sum (that is, the first total current value) of current values of current flowing through bit lines BL0 and BL1, which is a positive result of a multiply-accumulate operation, is greater than a sum (the third total current value) of current values of current flowing through bit lines BL2 and BL3, which is a negative result of a multiply-accumulate operation, or stated differently, when all the results of a multiply-accumulate operation are positive values, data 1 is output. In order to output data in such a manner, current values of current flowing through bit lines BL0, BL1, BL2, and BL3 are detected and determined, so that neural network computation of neuron 10 can be performed using computation unit PUi that includes variable resistance elements RPA0, RPB0, RNA0, and RNB0.

Next, with regard to a method of storing connection weight coefficients of the neural network computation circuit configured as above into variable resistance elements, three storing methods 1 to 3 are to be described in detail for their purposes in the following.

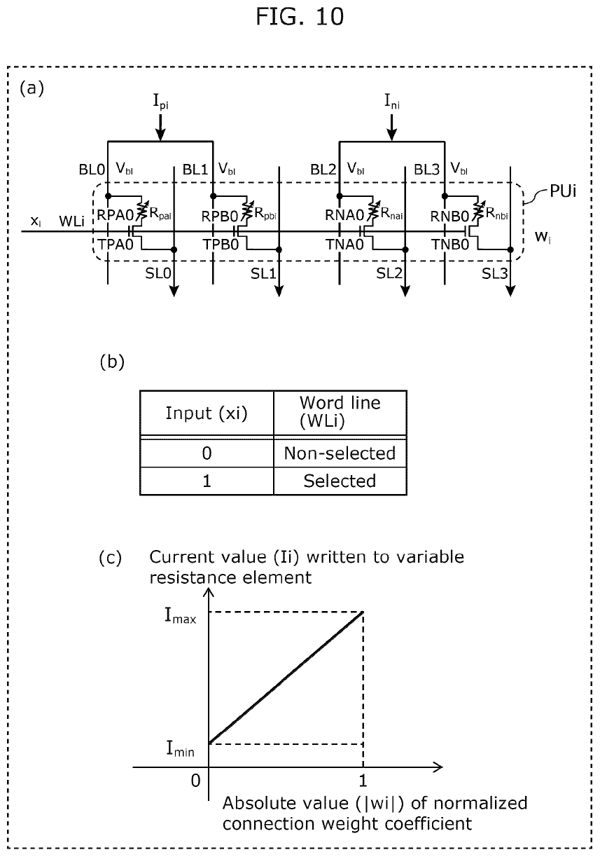

First, common points for three storing methods 1 to 3 are to be described with reference to FIG. 10. FIG. 10 illustrates a detailed operation of the computation unit according to the embodiment.

Part (a) of FIG. 10 illustrates operation of computation unit PUi. Part (a) of FIG. 10 is the same as (b) of FIG. 9, and thus a detailed description is omitted. A multiply-accumulate operation on input xi and connection weight coefficient wi in computation unit PUi is to be described.

Part (b) of FIG. 10 illustrates a state of word line WLi in response to input xi to computation unit PUi according to the embodiment. Input xi takes on a value of either data 0 or data 1, and when input xi is data 0, word line WLi is in a non-selected state, and when input xi is data 1, word line WLi is in a selected state. Word line WLi is connected to the gate terminals of cell transistors TPA0, TPB0, TNA0, and TNB0, and when word line WLi is in the non-selected state, cell transistors TPA0, TPB0, TNA0, and TNB0 are in a non-activated state (a blocked state), and current does not flow through bit line BL0, BL1, BL2, or BL3 irrespective of resistance values Rpai, Rpbi, Rnai, and Rnbi of variable resistance elements RPA0, RPB0, RNA0, and RNB0. On the other hand, when word line WLi is in a selected state, cell transistors TPA0, TPB0, TNA0, and TNB0 are in an activated state (that is, a connected state), and current flows through bit lines BL0, BL1, BL2, and BL3 based on resistance values Rpai, Rpbi, Rnai, and Rnbi of variable resistance elements RPA0, RPB0, RNA0, and RNB0.

Part (c) of FIG. 10 illustrates a current range of variable resistance elements RPA, RPB, RNA, and RNB of computation unit PUi according to the embodiment. A possible range of a current value of current flowing through variable resistance elements RPA, RPB, RNA, and RNB is to be described while the range is from minimum value Imin to maximum value Imax. Absolute value |wi| of a connection weight coefficient input to a neuron is normalized to cause the absolute value to be in a range of 0 to 1, and a current value to be written to a variable resistance element is to be determined to obtain a current value (that is, an analog value) proportional to normalized connection weight coefficient |wi|.

### <Connection Weight Coefficient Storing Method 1>

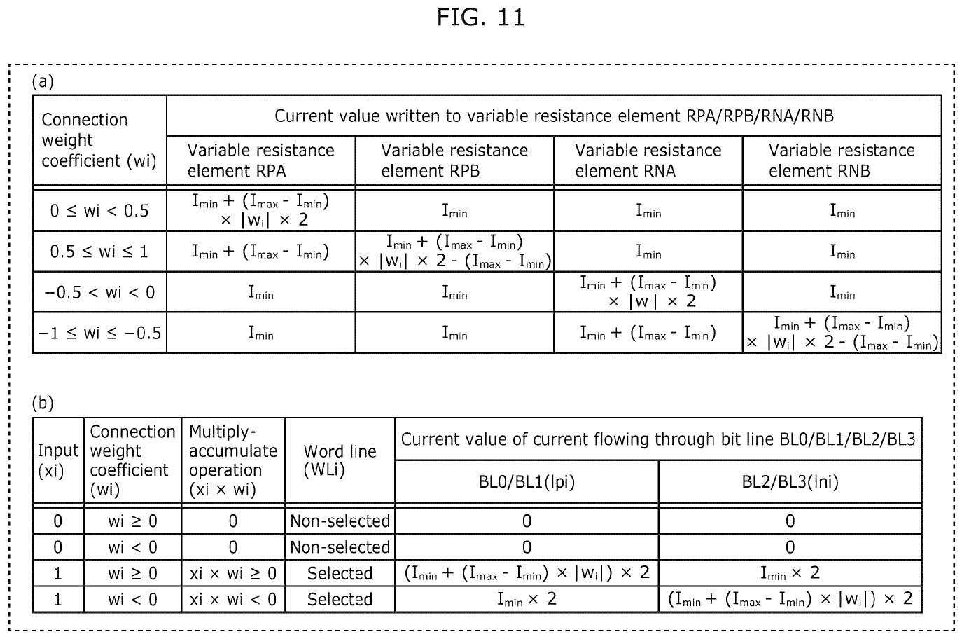

FIG. 11 is a drawing for explaining a method for writing, by using storing method 1, a connection weight coefficient to a variable resistance element in a computation unit according to the embodiment. Part (a) of FIG. 11 illustrates calculations of current values for writing connection weight coefficients to variable resistance elements RPA, RPB, RNA, and RNB of computation unit PUi by using storing method 1.

When connection weight coefficient wi has a positive value (≥0) and is smaller than one half (<0.5), with storing method 1, connection weight coefficient wi (≥0) is obtained by using a current value twice current value Imax that can be written to one memory cell, and thus a result of a multiply-accumulate operation (≥0) on input xi (data 0 or data 1) and connection weight coefficient wi (≥0) is added, as a current value, to bit line BL0 through which current that is a positive result of the multiply-accumulate operation flows. Accordingly, resistance value Rpai that allows a flow of current having current value Imin+(Imax−Imin)×|wi|×2 proportional to absolute value |wi| of a connection weight coefficient is written to variable resistance element RPA connected to bit line BL0. Furthermore, resistance values Rpbi, Rnai, and Rnbi that result in current value Imin (corresponding to a connection weight coefficient of 0) are written to variable resistance elements RPB, RNA, and RNB connected to bit lines BL1, BL2, and BL3, respectively.

Next, when connection weight coefficient wi has a positive value (≥0) and is greater than or equal to one half (≥0.5), the neural network computation circuit according to the present disclosure writes resistance value Rpai that allows a current flow having current value Imin+(Imax−Imin) to variable resistance element RPA connected to bit line BL0, since connection weight coefficient wi (≥0) is obtained by using a current value twice current value Imax that can be written to one memory cell. Furthermore, resistance value Rpbi that allows a current flow having current value Imin+(Imax−Imin)×|wi|×2−(Imax−Imin) is written to variable resistance element RPB connected to bit line BL1. Moreover, resistance values Rnai and Rnbi that result in current value Imin (corresponding to a connection weight coefficient of 0) are written to variable resistance elements RNA and RNB connected to bit lines BL2 and BL3.

On the other hand, when connection weight coefficient wi has a negative value (<0) and is greater than one half (>0.5), the neural network computation circuit according to the present disclosure writes resistance value Rnai that allows a current flow having current value Imin+(Imax−Imin)×|wi|×2 proportional to absolute value |wi| of a connection weight coefficient to variable resistance element RNA connected to bit line BL2, since connection weight coefficient wi (<0) is obtained by using a current value twice current value Imax that can be written to one memory cell. Furthermore, resistance values Rpai, Rpbi, and Rnbi that result incurrent value Imin (corresponding to a connection weight coefficient of 0) are written to variable resistance elements RPA, RPB, and RNB connected to bit lines BL0, BL1, and BL3.

Next, when connection weight coefficient wi has a negative value (<0) and is less than or equal to one half (≤−0.5), the neural network computation circuit according to the present disclosure writes resistance value Rnai that allows a current flow having current value Imin+(Imax−Imin) to variable resistance element RNA connected to bit line BL2, since connection weight coefficient wi (<0) is obtained by using a current value twice current value Imax that can be written to one memory cell. Furthermore, resistance value Rnbi that allows a current flow having current value Imin+(Imax−Imin)×|wi|×2−(Imax−Imin) is written to variable resistance element RNB connected to bit line BL3. Furthermore, resistance values Rpai and Rpbi that result in current value Imin (corresponding to a connection weight coefficient of 0) are written to variable resistance elements RPA and RPB connected to bit lines BL0 and BL1.

By setting resistance values (current values) that are written to variable resistance elements RPA, RPB, RNA, and RNB as described above, according to storing method 1, a difference current (Imax−Imin)×|wi|×2 between a sum (corresponding to a positive result of a multiply-accumulate operation) of current values of current flowing through bit lines BL0 and BL1 and a sum (corresponding to a negative result of a multiply-accumulate operation) of current values of current flowing through bit lines BL2 and BL3 can be obtained as a current value corresponding to a result of a multiply-accumulate operation on inputs and connection weight coefficients. Details of a method for normalizing absolute value |wi| of a connection weight coefficient to be in a range of 0 to 1 are to be described later.

Part (b) of FIG. 11 illustrates multiply-accumulate operations on input xi and connection weight coefficient wi performed by computation unit PUi to which a connection weight coefficient has been written by using storing method 1.

When input xi has data 0, a result of a multiply-accumulate operation xi×wi is 0 irrespective of a value of connection weight coefficient wi. Since input xi has data 0, word line WLi is in a non-selected state, and cell transistors TPA0, TPB0, TNA0, and TNB0 are in a non-activated state (blocked state), and thus current values Ipi and Ini of current flowing through bit lines BL0, BL1, BL2, and BL3 are 0. Thus, since the result of multiply-accumulate operation xi×wi is 0, no current flows through bit lines BL0 and BL1 through which current corresponding to a positive result of a multiply-accumulate operation flows or bit lines BL2 and BL3 through which current corresponding to a negative result of a multiply-accumulate operation flows.

When input xi has data 1 and connection weight coefficient wi has a positive value (≥0), the result of multiply-accumulate operation xi×wi is a positive value (≥0). Since input xi is data 1, word line WLi is in a selected state and cell transistors TPA0, TPB0, TNA0, and TNB0 are in an activated state (a connected state), current Ipi and current Ini described with reference to (a) of FIG. 11 flow through bit lines BL0, BL1, BL2, and BL3, based on the resistance values of variable resistance elements RPA, RPB, RNA, and RNB. Difference current ((Imax−Imin)×|wi|)×2 between current Ipi corresponding to a positive result of a multiply-accumulate operation and flowing through bit lines BL0 and BL1 and current Ini corresponding to a negative result of a multiply-accumulate operation and flowing through bit lines BL2 and BL3 flows more through bit lines BL0 and BL1 than BL2 and BL3, as current corresponding to a result of a multiply-accumulate operation xi×wi (≥0) on input xi and connection weight coefficient wi.

On the other hand, when input xi has data 1 and connection weight coefficient wi has a negative value (<0), the result of multiply-accumulate operation xi×wi is a negative value (<0). Since input xi is data 1, word line WLi is in a selected state and cell transistors TPA0, TPB0, TNA0, and TNB0 are in an activated state (a connected state), current Ipi and current Ini described with reference to (a) of FIG. 11 flow through bit lines BL0, BL1, BL2, and BL3, based on the resistance values of variable resistance elements RPA, RPB, RNA, and RNB. Difference current ((Imax−Imin)×|wi|)×2 between current Ipi corresponding to a positive result of a multiply-accumulate operation and flowing through bit lines BL0 and BL1 and current Ini corresponding to a negative result of a multiply-accumulate operation and flowing through bit lines BL2 and BL3 flows more through bit lines BL2 and BL3 than BL0 and BL1, as current corresponding to a result of a multiply-accumulate operation xi×wi (≤0) on input xi and connection weight coefficient wi.

Hence, according to storing method 1, current corresponding to a result of a multiply-accumulate operation on input xi and connection weight coefficient wi flows through bit lines BL0, BL1, BL2, and BL3, and in the case of a positive result of the multiply-accumulate operation, the current flows more through bit lines BL0 and BL1 than bit lines BL2 and BL3, whereas in the case of a negative result of the multiply-accumulate operation, the current flows more through bit lines BL2 and BL3 than bit lines BL0 and BL1. Computation units PUi, the number of which is the same as the number of inputs x0 to xn (connection weight coefficients w0 to wn), are connected in parallel to bit lines BL0, BL1, BL2, and BL3, and thus a result of the multiply-accumulate operation of neuron 10 can be obtained as difference current between current flowing through bit lines BL0 and BL1 and current flowing through bit lines BL2 and BL3.

Here, when a sum of current values of current flowing through bit lines BL0 and BL1 is smaller than a sum of current values of current flowing through bit lines BL2 and BL3, that is, when the result of a multiply-accumulate operation is a negative value, output data of data 0 is output using the determination circuit connected to bit lines BL0, BL1, BL2, and BL3, whereas when a sum of current values of current flowing through bit lines BL0 and BL1 is greater than a sum of current values of current flowing through bit lines BL2 and BL3, that is, when the result of a multiply-accumulate operation is a positive value, output data of data 1 is output using the determination circuit. This corresponds to the determination circuit performing computation of an activation function that is a step function, and thus neural network computation for a multiply-accumulate operation and computation processing of an activation function can be performed.

According to storing method 1, as compared to conventional technology with which each computation unit includes two memory cells, the current value of current flowing through each computation unit can be doubled (or stated differently, a dynamic range can be increased), and performance of a multiply-accumulate operation in a neural network computation circuit can be enhanced.

Note that according to storing method 1, in order to simplify description, a computation unit in which a positive weight coefficient is included in two memory cells and a negative weight coefficient is included in two memory cells has been described as an example, yet a positive weight coefficient and a negative weight coefficient can each be included in one memory cell to n memory cells, and thus are not limited to be each included in two memory cells. In this case, connection weight coefficient wi can be obtained by using an n-time current value. The neural network computation circuit according to the present disclosure has a feature that at least one of a positive weight coefficient or a negative weight coefficient is included in two or more memory cells.

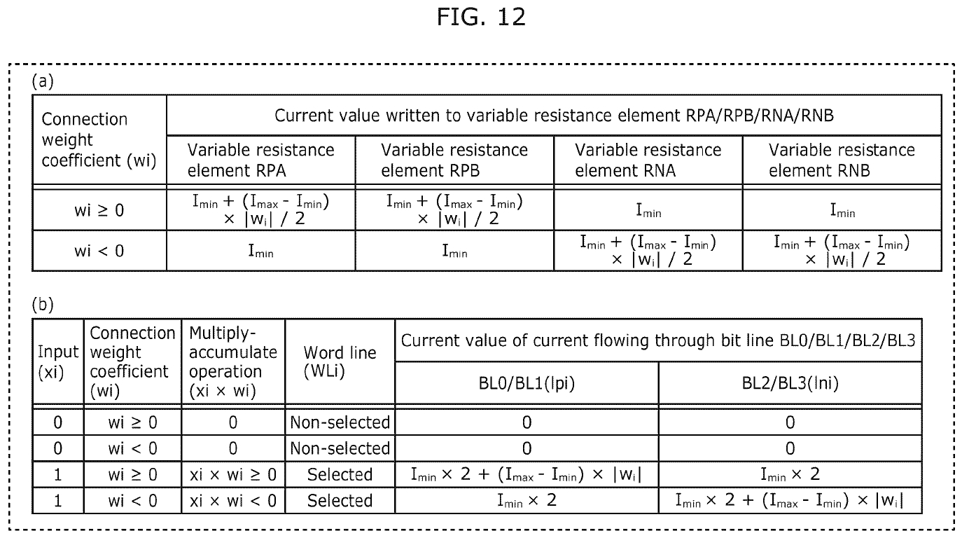

FIG. 12 is a drawing for explaining a method for writing, by using storing method 2, a connection weight coefficient to a variable resistance element in a computation unit according to the embodiment. Part (a) of FIG. 12 illustrates calculations of current values for writing connection weight coefficients to variable resistance elements RPA, RPB, RNA, and RNB of computation unit PUi by using storing method 2. With storing method 2, since connection weight coefficient wi (≥0) is obtained by using a current value half current value Imax that can be written to one memory cell, when connection weight coefficient wi is a positive value (≥0), with regard to the result (≥0) of a multiply-accumulate operation (≥0) on input xi (data 0 or data 1) and connection weight coefficient wi (≥0), resistance value Rpai that allows a flow of current having Imin+(Imax−Imin)×|wi|/2 that is half the current value proportional to absolute value |wi| of the connection weight coefficient is written to variable resistance element RPA connected to bit line BL0 through which current that is a positive result of a multiply-accumulate operation flows. Similarly, in order to add current flowing through bit line BL0 as a current value to also bit line BL1, resistance value Rpbi that allows a flow of current Imin+(Imax−Imin)×|wi|/2 that is a half the current value proportional to absolute value |wi| of the connection weight coefficient is written to variable resistance element RPB connected to bit line BL1. Furthermore, resistance values Rnai and Rnbi that result in current value Imin (corresponding to a connection weight coefficient of 0) are written to variable resistance elements RNA and RNB connected to bit lines BL2 and BL3.

On the other hand, when connection weight coefficient wi is a negative value (<0), with regard to the result (<0) of a multiply-accumulate operation on input xi (data 0 or data 1) and connection weight coefficient wi (<0), resistance value Rnai that allows a flow of current having Imin+(Imax−Imin)×|wi|/2 that is half the current value proportional to absolute value |wi| of the connection weight coefficient is written to variable resistance element RNA connected to bit line BL2 through which current that is a negative result of a multiply-accumulate operation flows. Similarly, in order to add current flowing through bit line BL2 as a current value to also bit line BL3, resistance value Rnbi that allows a flow of current Imin+(Imax−Imin)×|wi|/2 that is a half the current value proportional to absolute value |wi| of the connection weight coefficient is written to variable resistance element RNB connected to bit line BL3. Furthermore, resistance values Rpai and Rpbi that result in current value Imin (corresponding to a connection weight coefficient of 0) are written to variable resistance elements RPA and RPB connected to bit lines BL0 and BL1.

By setting resistance values (current values) that are written to variable resistance elements RPA, RPB, RNA, and RNB as described above, according to storing method 2, a difference current (Imax−Imin)×|wi| between a sum (corresponding to a positive result of a multiply-accumulate operation) of current values of current flowing through bit lines BL0 and BL1 and a sum (corresponding to a negative result of a multiply-accumulate operation) of current values of current flowing through bit lines BL2 and BL3 can be obtained as a current value corresponding to a result of a multiply-accumulate operation on inputs and connection weight coefficients. Details of a method for normalizing absolute value |wi| of a connection weight coefficient to be in a range of 0 to 1 are to be described later.

Part (b) of FIG. 12 illustrates a multiply-accumulate operation on input xi and connection weight coefficient wi performed by computation unit PUi to which a connection weight coefficient has been written by using storing method 2.

The case where input xi is data 0 is the same as the case in (b) of FIG. 11, and thus a detailed description thereof is omitted here.

When input xi has data 1 and connection weight coefficient wi has a positive value (≥0), the result of multiply-accumulate operation xi×wi is a positive value (≥0). Since input xi is data 1, word line WLi is in a selected state and cell transistors TPA0, TPB0, TNA0, and TNB0 are in an activated state (a connected state), current Ipi and current Ini described with reference to (a) of FIG. 12 flow through bit lines BL0, BL1, BL2, and BL3, based on the resistance values of variable resistance elements RPA, RPB, RNA, and RNB. Difference current ((Imax−Imin)×|wi|) between current Ipi corresponding to a positive result of a multiply-accumulate operation and flowing through bit lines BL0 and BL1 and current Ini corresponding to a negative result of a multiply-accumulate operation and flowing through bit lines BL2 and BL3 flows more through bit lines BL0 and BL1 than BL2 and BL3, as current corresponding to the result of multiply-accumulate operation xi×wi (≥0) on input xi and connection weight coefficient wi.

On the other hand, when input xi has data 1 and connection weight coefficient wi has a negative value (<0), the result of multiply-accumulate operation xi×wi is a negative value (<0). Since input xi is data 1, word line WLi is in a selected state and cell transistors TPA0, TPB0, TNA0, and TNB0 are in an activated state (ca connected state), current Ipi and current Ini described with reference to (a) of FIG. 12 flow through bit lines BL0, BL1, BL2, and BL3, based on the resistance values of variable resistance elements RPA, RPB, RNA, and RNB. Difference current ((Imax−Imin)×|wi|) between current Ipi corresponding to a positive result of a multiply-accumulate operation and flowing through bit lines BL0 and BL1 and current Ini corresponding to a negative result of a multiply-accumulate operation and flowing through bit lines BL2 and BL3 flows more through bit lines BL2 and BL3 than BL0 and BL1, as current corresponding to a result of multiply-accumulate operation xi×wi (≤0) on input xi and connection weight coefficient wi.

As described above, according to storing method 2, current corresponding to a result of a multiply-accumulate operation on input xi and connection weight coefficient wi flows through bit lines BL0, BL1, BL2, and BL3, and in the case of a positive result of the multiply-accumulate operation, the current flows more through bit lines BL0 and BL1 than bit lines BL2 and BL3, whereas in the case of a negative result of the multiply-accumulate operation, the current flows more through bit lines BL2 and BL3 than bit lines BL0 and BL1. Computation units PUi, the number of which is the same as the number of inputs x0 to xn (connection weight coefficients w0 to wn), are connected in parallel to bit lines BL0, BL1, BL2, and BL3, and thus a result of a multiply-accumulate operation of neuron 10 can be obtained as a difference current between current flowing through bit lines BL0 and BL1 and current flowing through bit lines BL2 and BL3.

Here, when a sum of current values of current flowing through bit lines BL0 and BL1 is smaller than a sum of current values of current flowing through bit lines BL2 and BL3, that is, when the result of a multiply-accumulate operation is a negative value, output data of data 0 is output using the determination circuit connected to bit lines BL0, BL1, BL2, and BL3, whereas when a sum of current values of current flowing through bit lines BL0 and BL1 is greater than a sum of current values of current flowing through bit lines BL2 and BL3, that is, when the result of a multiply-accumulate operation is a positive value, output data of data 1 is output using the determination circuit. This corresponds to the determination circuit performing computation of an activation function that is a step function, and thus neural network computation for a multiply-accumulate operation and computation processing of an activation function can be performed.

According to storing method 1, as compared to conventional technology with which each computation unit includes two memory cells, the current value of current flowing through each computation unit can be halved, and performance of a multiply-accumulate operation in a neural network computation circuit can be enhanced.

Note that according to storing method 2, in order to simplify description, a computation unit in which a positive weight coefficient is included in two memory cells and a negative weight coefficient is included in two memory cells has been described as an example, yet a positive weight coefficient and a negative weight coefficient can each be included in one memory cell to n memory cells, and thus are not limited to be each included in two memory cells. In this case, connection weight coefficient wi can be obtained using a one-nth current value. The neural network computation circuit according to the present disclosure has a feature that at least one of a positive weight coefficient or a negative weight coefficient is included in two or more memory cells.

### <Connection Weight Coefficient Storing Method 3>

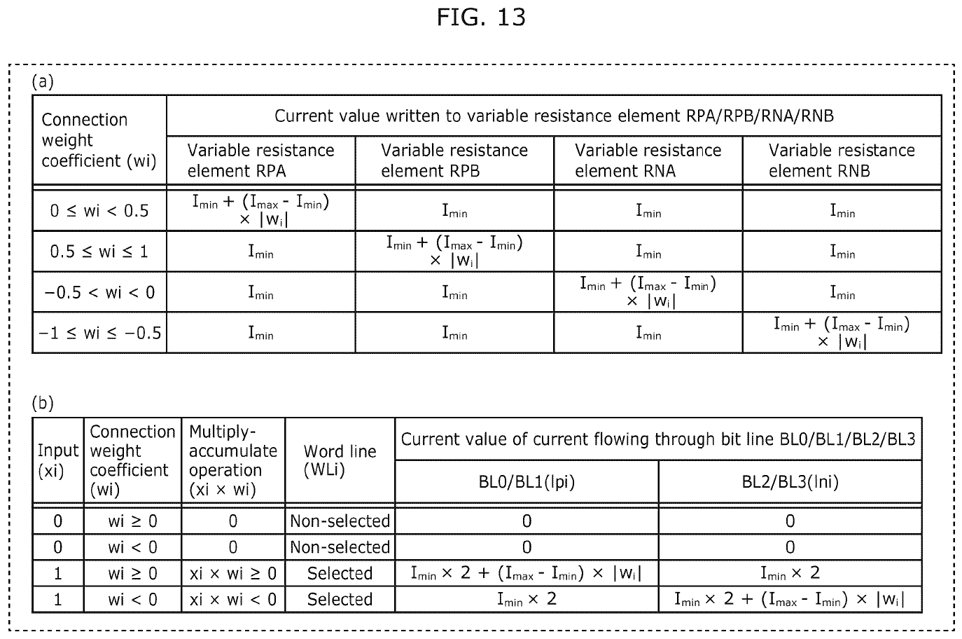

FIG. 13 is a drawing for explaining a method for writing, by using storing method 3, a connection weight coefficient to a variable resistance element in a computation unit according to the embodiment. Part (a) of FIG. 13 illustrates calculations of current values for writing connection weight coefficients to variable resistance elements RPA, RPB, RNA, and RNB of computation unit PUi using storing method 3.

When connection weight coefficient wi is a positive value (≥0) and less than one half (<0.5), in order to add, as a current value, a result (≥0) of a multiply-accumulate operation on input xi (data 0 or data 1) and connection weight coefficient wi (≥0) to bit line BL0 through which current that is a positive result of a multiply-accumulate operation flows, resistance value Rpai that allows a flow of current having current value Imin+(Imax−Imin)×|wi| proportional to absolute value |wi| of the connection weight coefficient is written to variable resistance element RPA connected to bit line BL0.

Here, with storing method 3, since a write algorithm is changed according to the magnitude of connection weight coefficient wi, when connection weight coefficient wi has a positive value (≥0) and is greater than or equal to one half (≥0.5), in order to add, as a current value, a positive result of a multiply-accumulate operation to bit line BL1, resistance value Rpbi that allows flow of current having current value Imin+(Imax−Imin)×|wi| proportional to absolute value |wi| of the connection weight coefficient is written to variable resistance element RPB connected to bit line BL1. Furthermore, resistance values Rnai and Rnbi that result in current value Imin (corresponding to a connection weight coefficient of 0) are written to variable resistance elements RNA and RNB connected to bit lines BL2 and BL3.

On the other hand, when connection weight coefficient wi is a negative value (<0) and is greater than one half (>−0.5), resistance value Rnai that allows a flow of current having current value Imin+(Imax−Imin)×|wi| proportional to absolute value |wi| of the connection weight coefficient is written to variable resistance element RNA connected to bit line BL2, in order to add, as a current value to bit line BL2 through which current that is a negative result of a multiply-accumulate operation flows, the result (<0) of the multiply-accumulate operation on input xi (data 0 or data 1) and connection weight coefficient wi (<0).

Here, with storing method 3, since a write algorithm is changed according to the magnitude of connection weight coefficient wi, when connection weight coefficient wi has a negative value (<0) and is less than or equal to one half (≤−0.5), in order to add, as a current value, a positive result of a multiply-accumulate operation to bit line BL3, resistance value Rnbi that allows flow of current having current value Imin+(Imax−Imin)×|wi| proportional to absolute value |wi| of the connection weight coefficient is written to variable resistance element RNB connected to bit line BL3. Furthermore, resistance values Rpai and Rpbi that result in current value Imin (corresponding to a connection weight coefficient of 0) are written to variable resistance elements RPA and RPB connected to bit lines BL0 and BL1.

By setting resistance values (current values) that are written to variable resistance elements RPA, RPB, RNA, and RNB as described above, according to storing method 3, difference current (Imax−Imin)×|wi| between a sum (corresponding to a positive result of a multiply-accumulate operation) of current values of current flowing through bit lines BL0 and BL1 and a sum (corresponding to a negative result of a multiply-accumulate operation) of current values of current flowing through bit lines BL2 and BL3 can be obtained as a current value corresponding to a result of a multiply-accumulate operation on inputs and connection weight coefficients. Details of a method for normalizing absolute value |wi| of a connection weight coefficient to be in a range of 0 to 1 are to be described later.

Part (b) of FIG. 13 illustrates a multiply-accumulate operation on input xi and connection weight coefficient wi performed by computation unit PUi to which a connection weight coefficient has been written by using storing method 3.

The case where input xi is data 0 is the same as the case in (b) of FIG. 11, and thus a detailed description thereof is omitted here.

When input xi has data 1 and connection weight coefficient wi has a positive value (≥0), the result of multiply-accumulate operation xi×wi is a positive value (≥0). Since input xi is data 1, word line WLi is in a selected state and cell transistors TPA0, TPB0, TNA0, and TNB0 are in an activated state (a connected state), current Ipi and current Ini described with reference to (a) of FIG. 13 flow through bit lines BL0, BL1, BL2, and BL3, based on the resistance values of variable resistance elements RPA, RPB, RNA, and RNB. Difference current ((Imax−Imin)×|wi|) between current Ipi corresponding to a positive result of a multiply-accumulate operation and flowing through bit lines BL0 and BL1 and current Ini corresponding to a negative result of a multiply-accumulate operation and flowing through bit lines BL2 and BL3 flows more through bit lines BL0 and BL1 than BL2 and BL3, as current corresponding to a result (≥0) of multiply-accumulate operation xi×wi on input xi and connection weight coefficient wi.

On the other hand, when input xi has data 1 and connection weight coefficient wi has a negative value (<0), the result of multiply-accumulate operation xi×wi is a negative value (<0). Since input xi is data 1, word line WLi is in a selected state and cell transistors TPA0, TPB0, TNA0, and TNB0 are in an activated state (a connected state), current Ipi and current Ini described with reference to (a) of FIG. 13 flow through bit lines BL0, BL1, BL2, and BL3, based on the resistance values of variable resistance elements RPA, RPB, RNA, and RNB. Difference current ((Imax−Imin)×|wi|) between current Ipi corresponding to a positive result of a multiply-accumulate operation and flowing through bit lines BL0 and BL1 and current Ini corresponding to a negative result of a multiply-accumulate operation and flowing through bit lines BL2 and BL3 flows more through bit lines BL2 and BL3 than BL0 and BL1, as current corresponding to a result (≤0) of multiply-accumulate operation xi×wi on input xi and connection weight coefficient wi.

As described above, according to storing method 3, current corresponding to a result of a multiply-accumulate operation on input xi and connection weight coefficient wi flows through bit lines BL0, BL1, BL2, and BL3, and in the case of a positive result of a multiply-accumulate operation, the current flows more through bit lines BL0 and BL1 than bit lines BL2 and BL3, whereas in the case of a negative result of a multiply-accumulate operation, the current flows more through bit lines BL2 and BL3 than bit lines BL0 and BL1. Computation units PUi, the number of which is the same as the number of inputs x0 to xn (connection weight coefficients w0 to wn), are connected in parallel to bit lines BL0, BL1, BL2, and BL3, and thus a result of a multiply-accumulate operation of neuron 10 can be obtained as difference current between current flowing through bit lines BL0 and BL1 and current flowing through bit lines BL2 and BL3.

Here, when a sum of current values of current flowing through bit lines BL0 and BL1 is smaller than a sum of current values of current flowing through bit lines BL2 and BL3, that is, when the result of a multiply-accumulate operation is a negative value, output data of data 0 is output using the determination circuit connected to bit lines BL0, BL1, BL2, and BL3, whereas when a sum of current values of current flowing through bit lines BL0 and BL1 is greater than a sum of current values of current flowing through bit lines BL2 and BL3, that is, when the result of a multiply-accumulate operation is a positive value, output data of data 1 is output using the determination circuit. This corresponds to the determination circuit performing computation of an activation function that is a step function, and thus neural network computation for a multiply-accumulate operation and computation processing of an activation function can be performed.

According to storing method 3, as compared with conventional technology with which each computation unit includes two memory cells, a semiconductor storage element to which a connection weight coefficient is to be written is changed to a different one according to the value of the connection weight coefficient, and thus a write algorithm can be changed, so that reliability of the semiconductor storage elements can be improved.

Note that according to storing method 3, in order to simplify description, a computation unit in which a positive weight coefficient is included in two memory cells and a negative weight coefficient is included in two memory cells has been described as an example, yet a positive weight coefficient and a negative weight coefficient can each be included in one memory cell to n memory cells, and thus are not limited to be each included in two memory cells. In this case, connection weight coefficient wi can be written using n types of write algorithms. The neural network computation circuit according to the present disclosure has a feature that at least one of a positive weight coefficient or a negative weight coefficient is included in two or more memory cells.

In the above, the three connection weight coefficient storing methods have been described based on an operation principle of a neural network computation circuit according to the present disclosure. In the following, specific current values when connection weight coefficients are stored using the three storing methods are to be described.

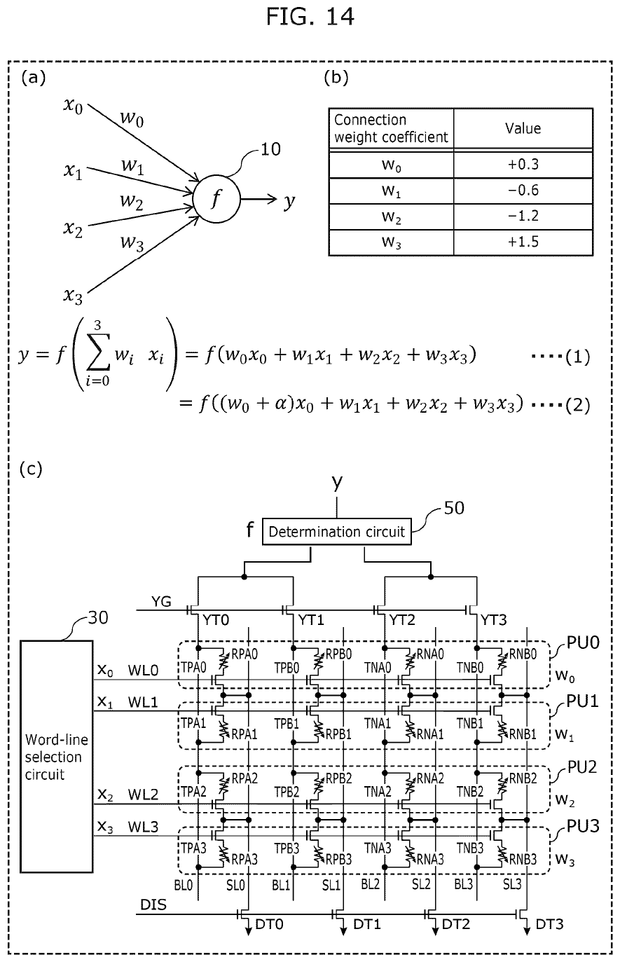

First, specific common points for three storing methods 1 to 3 are to be described with reference to FIG. 14. FIG. 14 is a drawing for explaining a configuration of a neural network computation circuit according to a specific example. Part (a) of FIG. 14 illustrates neuron 10 included in the neural network computation circuit according to the specific example. Part (b) of FIG. 14 illustrates specific examples of connection weight coefficients of neuron 10 illustrated in (a) of FIG. 14. As illustrated in (a) of FIG. 14, neuron 10 has connection weight coefficients w0 to w3 corresponding to four inputs x0 to x3, and computation performed by neuron 10 is shown by Expression (1) in (a) of FIG. 14. Activation function f of neuron 10 is a step function.

As illustrated in (b) of FIG. 14, connection weight coefficients that neuron 10 has are w0=+0.3, w1=−0.6, w2=−1.2, and w3=+1.5.

Part (c) of FIG. 14 illustrates a detailed configuration of a neural network computation circuit according to the specific example. A neural network computation circuit according to this specific example is a four-input, one-output neuron, and includes four computation units PU0 to PU3 that store connection weight coefficients w0 to w3, four word lines WL0 to WL3 corresponding to inputs x0 to x3, bit line BL0 and source SL0 to which variable resistance elements RPA0, RPA1, RPA2, and RPA3 and cell transistors TPA0, TPA1, TPA2, and TPA3 are connected, bit line BL1 and source SL1 to which variable resistance elements RPB0, RPB1, RPB2, and RPB3 and cell transistors TPB0, TPB1, TPB2, and TPB3 are connected, bit line BL2 and source SL2 to which variable resistance elements RNA0, RNA1, RNA2, and RNA3 and cell transistors TNA0, TNA1, TNA2, and TNA3 are connected, and bit line BL3 and source SL3 to which variable resistance elements RNB0, RNB1, RNB2, and RNB3 and cell transistors TNB0, TNB1, TNB2, and TNB3 are connected.

When a neural network computation operation is performed, word lines WL0 to WL3 are each placed in a selected or non-selected state and cell transistors TPA0 to TPA3, TPB0 to TPB3, TNA0 to TNA3, and TNB0 to TNB3 of computation units PU0 to PU3 are each placed in a selected or non-selected state, according to inputs x0 to x3. A bit line voltage is supplied from determination circuit 50 to bit lines BL0, BL1, BL2, and BL3 through column gates YT0, YT1, YT2, and YT3, respectively, and source lines SL0, SL1, SL2, and SL3 are connected to a ground voltage source via discharge transistors DT0, DT1, DT2, and DT3, respectively. Accordingly, current corresponding to a positive result of a multiply-accumulate operation flows through bit lines BL0 and BL1, and current corresponding to a negative result of a multiply-accumulate operation flows through bit lines BL2 and BL3. Determination circuit 50 detects and determines a magnitude relation of a sum of current flowing through bit lines BL0 and BL1 and a sum of current flowing through bit lines BL2 and BL3, and outputs output y. Specifically, when a result of a multiply-accumulate operation of neuron 10 is a negative value (<0), determination circuit 50 outputs data 0, whereas when a result of a multiply-accumulate operation of neuron 10 is a positive value (≥0), determination circuit 50 outputs data 1. Determination circuit 50 outputs a result of computation of activation function f (a step function) using a result of a multiply-accumulate operation as an input.

### <Specific Example of Current Value According to Storing Method 1>

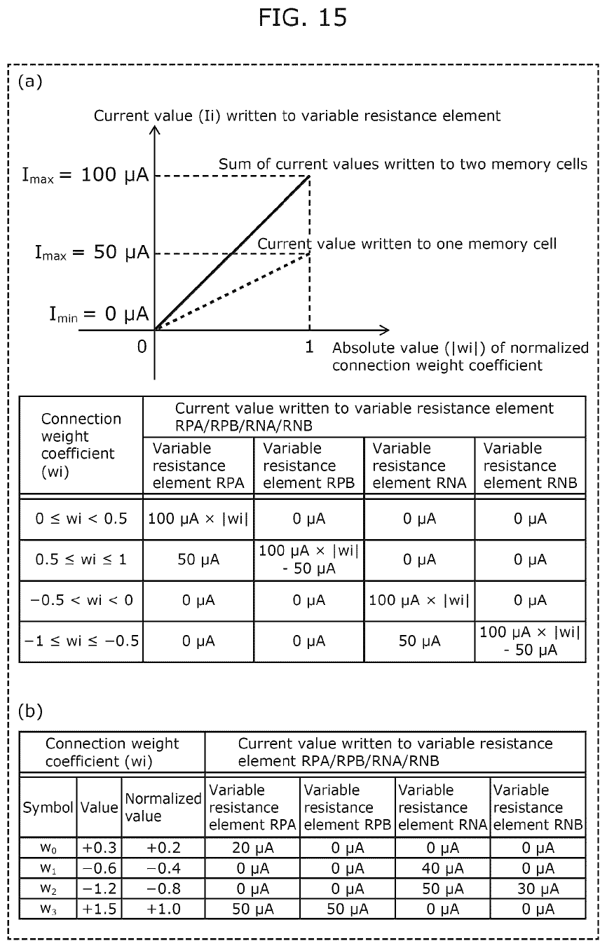

FIG. 15 illustrates specific examples of current values according to storing method 1. More specifically, (a) and (b) of FIG. 15 illustrate current ranges of variable resistance elements RPA, RPB, RNA, and RNB of computation units PU0 to PU3 and current values that are written to variable resistance elements RPA, RPB, RNA, and RNB when connection weight coefficients are written by using storing method 1. As illustrated in (a) of FIG. 15, with storing method 1, a possible range of current values of current flowing through memory cells of variable resistance elements RPA, RPB, RNA, and RNB is 0 μA to 50 μA. With regard to a sum of current values of current flowing through variable resistance elements RPA and RPB and a sum of current values of current flowing through variable resistance elements RNA and RNB, minimum value Imin of the current values is 0 μA and maximum value Imax of the current values is 100 μA, so that a current range (dynamic range) of 100 μA is used.

As shown by “Normalized value” in (b) of FIG. 15, connection weight coefficients w0 to w3 are first normalized to be in a range of 0 to 1. In the present embodiment, a connection weight coefficient having the greatest absolute value among connection weight coefficients w0 to w3 is w3=+1.5, and the value resulting from normalizing the connection weight coefficient is w3=+1.0. The values resulting from normalizing the remaining connection weight coefficients by the normalization are w0=+0.2, w1=−0.4, and w2=−0.8.

Next, as illustrated in (a) of FIG. 15, current values to be written to variable resistance elements RPA, RPB, RNA, and RNB of computation units PU0 to PU3 are determined by using the normalized connection weight coefficients. Part (b) of FIG. 15 illustrates results of calculating current values to be written to variable resistance elements RPA, RPB, RNA, and RNB. The normalized value of connection weight coefficient w0 is a positive value of +0.2 and thus is smaller than +0.5. Accordingly, the current value to be written to variable resistance element RPA is 20 μA, the current value to be written to variable resistance element RPB is 0 μA, the current value to be written to variable resistance element RNA is 0 μA, and the current value to be written to variable resistance element RNB is 0 μA. The normalized value of connection weight coefficient w1 is a negative value of −0.4 and thus is greater than −0.5. Accordingly, the current value to be written to variable resistance element RPA is 0 μA, the current value to be written to variable resistance element RPB is 0 μA, the current value to be written to variable resistance element RNA is 40 μA, and the current value to be written to variable resistance element RNB is 0 μA. The normalized value of connection weight coefficient w2 is a negative value of −0.8 and thus is less than or equal to −0.5. Accordingly, the current value to be written to variable resistance element RPA is 0 μA, the current value to be written to variable resistance element RPB is 0 μA, the current value to be written to variable resistance element RNA is 50 μA, and the current value to be written to variable resistance element RNB is 30 μA. The normalized value of connection weight coefficient w3 is a positive value of +1.0 and thus is greater than or equal to +0.5. Accordingly, the current value to be written to variable resistance element RPA is 50 μA, the current value to be written to variable resistance element RPB is 50 μA, the current value to be written to variable resistance element RNA is 0 μA, and the current value to be written to variable resistance element RNB is 0 μA. Neural network computation can be performed by writing resistance values corresponding to the above current values to variable resistance elements RPA, RPB, RNA, and RNB of computation units PU0 to PU3.

By obtaining a computation unit using four bits of variable resistance elements in the above manner, the dynamic range of 50 μA with two bits of variable resistance elements can be increased and a dynamic range of 100 μA can be used.

Note that in the specific example according to storing method 1, in order to simplify description, a computation unit in which a positive weight coefficient is included in two memory cells and a negative weight coefficient is included in two memory cells has been described as an example, yet a positive weight coefficient and a negative weight coefficient can each be included in one memory cell to n memory cells, and thus are not limited to be each included in two memory cells. The neural network computation circuit according to the present disclosure has a feature that at least one of a positive weight coefficient or a negative weight coefficient is included in two or more memory cells.

### <Specific Example of Current Value According to Storing Method 2>

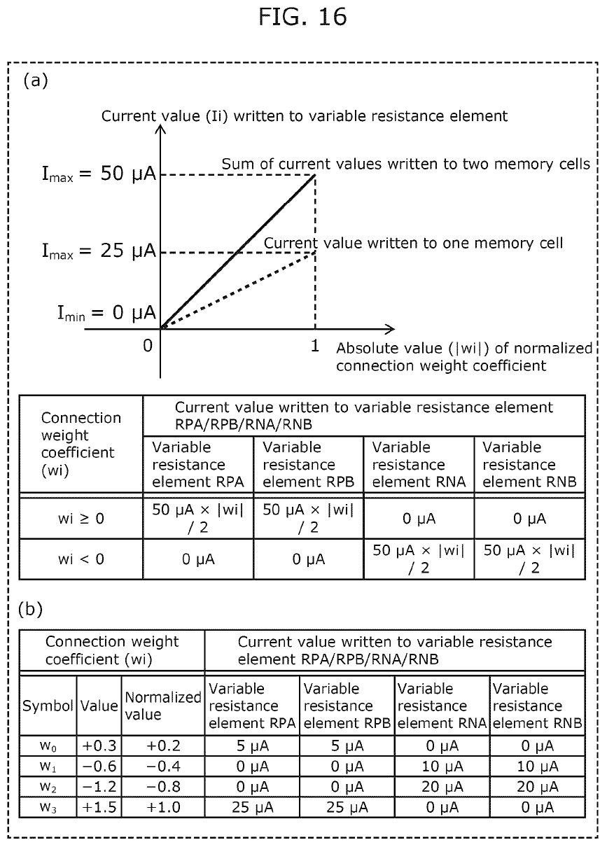

FIG. 16 illustrates specific examples of current values according to storing method 2. More specifically, (a) and (b) of FIG. 16 illustrate current ranges of variable resistance elements RPA, RPB, RNA, and RNB of computation units PU0 to PU3 and current values that are written to variable resistance elements RPA, RPB, RNA, and RNB when connection weight coefficients are written by using storing method 2. As illustrated in (a) of FIG. 16, with storing method 2, a possible range of current values of current flowing through memory cells of variable resistance elements RPA, RPB, RNA, and RNB is 0 μA to 25 μA. This is a half the current value that can be written to each memory cell. With regard to a sum of current values of current flowing through variable resistance elements RPA and RPB and a sum of current values of current flowing through variable resistance elements RNA and RNB, minimum value Imin of the current values is 0 μA and maximum value Imax of the current values is 50 μA, so that a current range (dynamic range) of 50 μA is used.

As illustrated by “Normalized value” in (b) of FIG. 16, connection weight coefficients w0 to w3 are first normalized to be in a range of 0 to 1. In the present embodiment, a connection weight coefficient having the greatest absolute value among connection weight coefficients w0 to w3 is w3=+1.5, and the value resulting from normalizing the connection weight coefficient is w3=+1.0. The values resulting from normalizing the remaining connection weight coefficients by the normalization are w0=+0.2, w1=−0.4, and w2=−0.8.

Next, as illustrated in (a) of FIG. 16, current values to be written to variable resistance elements RPA, RPB, RNA, and RNB of computation units PU0 to PU3 are determined by using the normalized connection weight coefficients. Part (b) of FIG. 16 illustrates results of calculating current values to be written to variable resistance elements RPA, RPB, RNA, and RNB. The normalized value of connection weight coefficient w0 is a positive value of +0.2. Accordingly, the current value to be written to variable resistance element RPA is 5 μA, the current value to be written to variable resistance element RPB is 5 μA, the current value to be written to variable resistance element RNA is 0 μA, and the current value to be written to variable resistance element RNB is 0 μA. The normalized value of connection weight coefficient w1 is a negative value of −0.4. Accordingly, the current value to be written to variable resistance element RPA is 0 μA, the current value to be written to variable resistance element RPB is 0 μA, the current value to be written to variable resistance element RNA is 10 μA, and the current value to be written to variable resistance element RNB is 10 μA. The normalized value of connection weight coefficient w2 is a negative value of −0.8. Accordingly, the current value to be written to variable resistance element RPA is 0 μA, the current value to be written to variable resistance element RPB is 0 μA, the current value to be written to variable resistance element RNA is 20 μA, and the current value to be written to variable resistance element RNB is 20 μA. The normalized value of connection weight coefficient w3 is a positive value of +1.0. Accordingly, the current value to be written to variable resistance element RPA is 25 μA, the current value to be written to variable resistance element RPB is 25 μA, the current value to be written to variable resistance element RNA is 0 μA, and the current value to be written to variable resistance element RNB is 0 μA. Neural network computation can be performed by writing resistance values corresponding to the above current values to variable resistance elements RPA, RPB, RNA, and RNB of computation units PU0 to PU3 in such a manner.

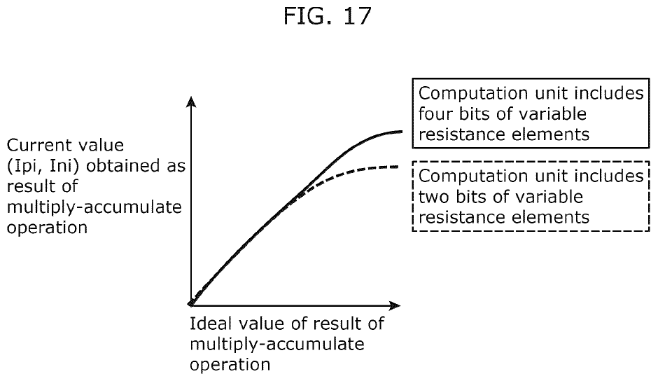

FIG. 17 illustrates a current value (the vertical axis) obtained as a result of a multiply-accumulate operation relative to an ideal value (the horizontal axis) of a result of the multiply-accumulate operation, by comparing conventional technology and the present embodiment. In a conventional neural network computation circuit, a computation unit includes two bits of variable resistance elements. Thus, a plurality of voltages having analog values corresponding to a plurality of inputs are applied to a plurality of nonvolatile memory elements, and an analog current value resulting from obtaining a sum of current values of current flowing through the plurality of nonvolatile memory elements is obtained as a result of a multiply-accumulate operation resulting from obtaining a sum of a positive result of a multiply-accumulate operation and a negative result of a multiply-accumulate operation on one bit line. Accordingly, the total analog current is saturated by being influenced by parasitic resistance and the control circuit, and a multiply-accumulate operation cannot be accurately performed.

On the other hand, in the neural network computation circuit according to the embodiment, a computation unit includes four bits of variable resistance elements. Thus, a plurality of voltages having analog values corresponding to a plurality of inputs are applied to a plurality of nonvolatile memory elements, and an analog current value resulting from obtaining a sum of current values of current flowing through the plurality of nonvolatile memory elements is obtained as a result of a multiply-accumulate operation resulting from obtaining separately a sum of each of a positive result of a multiply-accumulate operation on two bit lines and a negative result of a multiply-accumulate operation on two bit lines. Thus, the total analog current is less likely to be influenced by parasitic resistance or the control circuit, and saturation is eased, so that a multiply-accumulate operation can be accurately performed.

Note that in the specific example according to storing method 2, in order to simplify description, a computation unit in which a positive weight coefficient is included in two memory cells and a negative weight coefficient is included in two memory cells has been described as an example, yet a positive weight coefficient and a negative weight coefficient can each be included in one memory cell to n memory cells, and thus are not limited to be each included in two memory cells. The neural network computation circuit according to the present disclosure has a feature that at least one of a positive weight coefficient or a negative weight coefficient is included in two or more memory cells.

### <Specific Example of Current Value According to Storing Method 3>

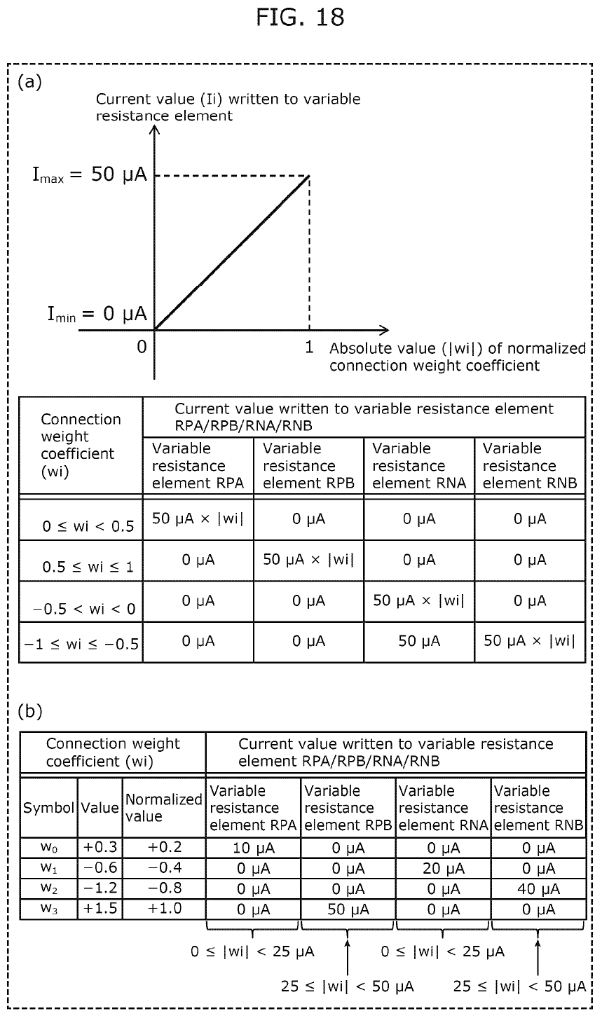

FIG. 18 illustrates specific examples of current values according to storing method 3. More specifically, (a) and (b) of FIG. 18 illustrate current ranges of variable resistance elements RPA, RPB, RNA, and RNB of computation units PU0 to PU3 and current values that are written to variable resistance elements RPA, RPB, RNA, and RNB when connection weight coefficients are written by using storing method 3. As illustrated in (a) of FIG. 18, with storing method 3, a possible range of current values of current flowing through memory cells of variable resistance elements RPA, RPB, RNA, and RNB is 0 μA to 50 μA. With regard to a sum of current values of current flowing through variable resistance elements RPA and RPB and a sum of current values of current flowing through variable resistance elements RNA and RNB, minimum value Imin of the current values is 0 μA and maximum value Imax of the current values is 50 μA, so that a current range (dynamic range) of 50 μA is used.

As shown by “Normalized value” in (b) of FIG. 18, connection weight coefficients w0 to w3 are first normalized to be in a range of 0 to 1. In the present embodiment, a connection weight coefficient having the greatest absolute value among connection weight coefficients w0 to w3 is w3=+1.5, and the value resulting from normalizing the connection weight coefficient is w3=+1.0. The values resulting from normalizing the remaining connection weight coefficients by the normalization are w0=+0.2, w1=−0.4, and w2=−0.8.

Next, as illustrated in (a) of FIG. 18, current values to be written to variable resistance elements RPA, RPB, RNA, and RNB of computation units PU0 to PU3 are determined by using the normalized connection weight coefficients. Part (b) of FIG. 18 illustrates results of calculating current values to be written to variable resistance elements RPA, RPB, RNA, and RNB. The normalized value of connection weight coefficient w0 is a positive value of +0.2, and a current value to be written is smaller than 25 μA. Accordingly, the current value to be written to variable resistance element RPA is 10 μA, the current value to be written to variable resistance element RPB is 0 μA, the current value to be written to variable resistance element RNA is 0 μA, and the current value to be written to variable resistance element RNB is 0 μA. The normalized value of connection weight coefficient w1 is a negative value of −0.4, and a current value to be written is smaller than 25 μA. Accordingly, the current value to be written to variable resistance element RPA is 0 μA, the current value to be written to variable resistance element RPB is 0 μA, the current value to be written to variable resistance element RNA is 20 μA, and the current value to be written to variable resistance element RNB is 0 μA. The normalized value of connection weight coefficient w2 is a negative value of −0.8, and a current value to be written is greater than or equal to 25 μA. Accordingly, the current value to be written to variable resistance element RPA is 0 μA, the current value to be written to variable resistance element RPB is 0 μA, the current value to be written to variable resistance element RNA is 0 μA, and the current value to be written to variable resistance element RNB is 40 μA. The normalized value of connection weight coefficient w3 is a positive value of +1.0, and a current value to be written is greater than or equal to 25 μA. Accordingly, the current value to be written to variable resistance element RPA is 0 μA, the current value to be written to variable resistance element RPB is 50 μA, the current value to be written to variable resistance element RNA is 0 μA, and the current value to be written to variable resistance element RNB is 0 μA. Neural network computation can be performed by writing resistance values corresponding to the above current values to variable resistance elements RPA, RPB, RNA, and RNB of computation units PU0 to PU3.

In this manner, by obtaining a computation unit using four bits of variable resistance elements, with storing method 3, a write algorithm according to a current value that is to be set can be used. In a variable resistance nonvolatile memory in particular, when a filament serving as a current path is formed in a variable resistance element in an inspection process, the size of this filament can be made a size according to the current value to be set, so that reliability of a variable resistance element is improved. This is effective in improving reliability of a variable resistance element, since also when a current value that is set to a computation unit is rewritten to another current value, the current value can be limited to be rewritten within the same current band.

Note that in the specific example according to storing method 3, in order to simplify description, a computation unit in which a positive weight coefficient is included in two memory cells and a negative weight coefficient is included in two memory cells has been described as an example, yet a positive weight coefficient and a negative weight coefficient can each be included in one memory cell to n memory cells, and thus are not limited to be each included in two memory cells. The neural network computation circuit according to the present disclosure has a feature that at least one of a positive weight coefficient or a negative weight coefficient is included in two or more memory cells.

### <Neural Network Computation Circuit According to Variation>

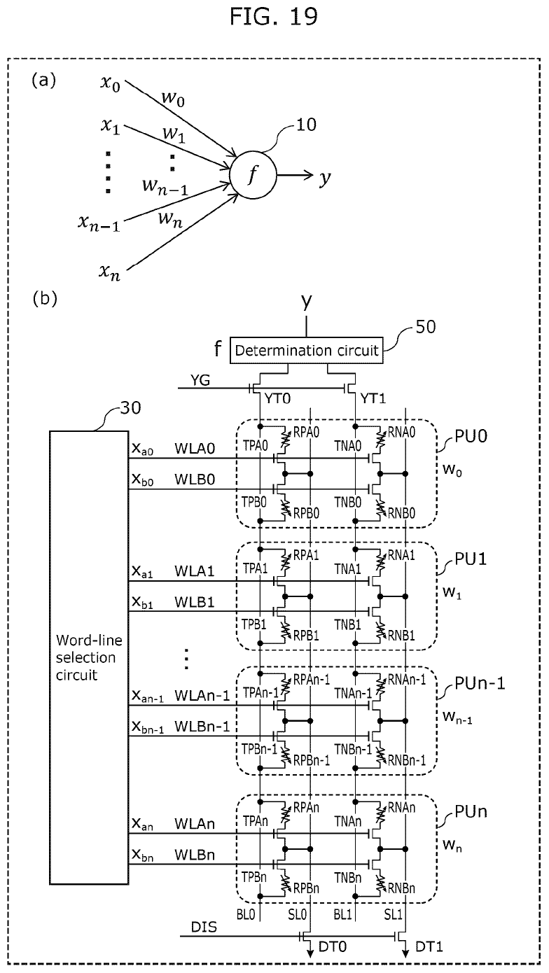

FIG. 19 illustrates a detailed configuration of a neural network computation circuit according to a variation of the embodiment.

Part (a) of FIG. 19 illustrates neuron 10 used in neural network computation performed by a neural network computation circuit according to a variation of the embodiment, and is the same as (a) of FIG. 1. N+1 inputs x0 to xn are input to neuron 10 with connection weight coefficients w0 to wn. Inputs x0 to xn may have either value of data 0 or data 1, and connection weight coefficients w0 to wn may take on a multi-level (analog) value. Computation of activation function f that is the step function illustrated in FIG. 5 is performed on a result of a multiply-accumulate operation on inputs x0 to xn and connection weight coefficients w0 to wn, and output y is output.

Part (b) of FIG. 19 illustrates a detailed configuration of a circuit that performs computation processing of neuron 10 in (a) of FIG. 19. In the embodiment, the computation unit has been described so far as being configured to include a single word line and four bit lines, but nevertheless, in this variation, the computation unit may be configured to include two word lines and two bit lines as illustrated in (b) of FIG. 19.

The memory cell array in (b) of FIG. 19 include plural word lines WLA0 to WLAn, plural word lines WLB0 to WLBn, plural bit lines BL0 and BL1, and plural source lines SL0 and SL1.

Inputs x0 to xn to neuron 10 are in correspondence with word lines WLA0 to WLAn and word lines WLB0 to WLBn, input x0 is in correspondence with word line WLA0 and word line WLB0, input x1 is in correspondence with word lines WLA1 and WLB1, input xn−1 is in correspondence with word lines WLAn−1 and WLBn−1, and input xn is in correspondence with word lines WLAn and WLBn.

Word-line selection circuit 30 places each of word lines WLA0 to WLAn and word lines WLB0 to WLBn in a selected or non-selected state, according to inputs x0 to xn, and at this time, performs the same control for word line WLA0 and word line WLB0, for word line WLA1 and word line WLB1, and for word line WLAn−1 and word line WLBn−1, and for word line WLAn and word line WLBn. When input is data 0, a word line is placed in a non-selected state, whereas when input is data 1, a word line is placed in a selected state. In neural network computation, inputs x0 to xn can each take on a value of data 0 or data 1, and thus when inputs x0 to xn include plural data 1 items, word-line selection circuit 30 selects plural word lines at the same time.

Computation units PU0 to PUn each including memory cells are in one-to-one correspondence with connection weight coefficients w0 to wn of neuron 10. Thus, connection weight coefficient w0 is in correspondence with computation unit PU0, connection weight coefficient w1 is in correspondence with computation unit PU1, connection weight coefficient wn−1 is in correspondence with computation unit PUn−1, and connection weight coefficient wn is in correspondence with computation unit PUn.

Computation unit PU0 includes a first memory cell that includes variable resistance element RPA0 as an example of a first semiconductor storage element and cell transistor TPA0 as an example of a first cell transistor that are connected in series, a second memory cell that includes variable resistance element RPB0 as an example of a second semiconductor storage element and cell transistor TPB0 as an example of a second cell transistor that are connected in series, a third memory cell that includes variable resistance element RNA0 as an example of a third semiconductor storage element and cell transistor TNA0 as an example of a third cell transistor that are connected in series, and a fourth memory cell that includes variable resistance element RNB0 as an example of a fourth semiconductor storage element and cell transistor TNB0 as an example of a fourth cell transistor that are connected in series. Thus, one computation unit includes four memory cells.

The first semiconductor storage element and the second semiconductor storage element are used to store a positive connection weight coefficient within one connection weight coefficient. The positive connection weight coefficient corresponds to a total current value that is a sum of a current value of current flowing through the first semiconductor storage element and a current value of current flowing through the second semiconductor storage element. In contrast, the third semiconductor storage element and the fourth semiconductor storage element are used to store a negative connection weight coefficient within one connection weight coefficient. The negative connection weight coefficient corresponds to a total current value that is a sum of a current value of current flowing through the third semiconductor storage element and a current value of current flowing through the fourth semiconductor storage element.

Computation unit PU0 is connected to word line WLA0 that is an example of a second word line, word line WLB0 that is an example of a third word line, bit line BL0 that is an example of a ninth data line, bit line BL1 that is an example of an eleventh data line, source line SL0 that is an example of a tenth data line, and source line SL1 that is an example of a twelfth data line. Word line WLA0 is connected to the gate terminals of cell transistors TPA0 and TNA0, word line WLB0 is connected to the gate terminals of cell transistors TPB0 and TNB0, bit line BL0 is connected to variable resistance elements RPA0 and RPB0, bit line BL1 is connected to variable resistance elements RNA0 and RNB0, source line SL0 is connected to the source terminals of cell transistors TPA0 and TPB0, and source line SL1 is connected to the source terminals of cell transistors TNA0 and TNB0. Input x0 is input through word lines WLA0 and WLB0 of computation unit PU0, and connection weight coefficient w0 is stored as a resistance value (conductance) in four variable resistance elements RPA0, RPB0, RNA0, and RNB0 of computation unit PU0.

A configuration of computation units PU1, PUn−1, and PUn is equivalent to the configuration of computation unit PU0, and thus detailed description thereof is omitted. Here, inputs x0 to xn are input through word lines WLA0 to WLAn and word lines WLB0 to WLBn connected to computation units PU0 to Pun, respectively, connection weight coefficients w0 to wn are stored as resistance values (conductance) in variable resistance elements RPA0 to RPAn, RPB0 to RPBn, RNA0 to RNAn, and RNB0 to RNBn of computation units PU0 to PUn.

Bit lines BL0 and BL1 are connected to determination circuit 50 via column gate transistors YT0 and YT1, respectively. The gate terminals of column gate transistors YT0 and YT1 are connected to column-gate control signal line YG, and when column-gate control signal line YG is activated, bit lines BL0 and BL1 are connected to determination circuit 50. Source lines SL0 and SL1 are connected to the ground voltage source via discharge transistors DT0 and DT1, respectively. The gate terminals of discharge transistors DT0 and DT1 are connected to discharge control signal line DIS, and when discharge control signal line DIS is activated, source lines SL0 and SL1 are set to the ground voltage. When a neural network computation operation is performed, by activating column-gate control signal line YG and discharge control signal line DIS, bit lines BL0 and BL1 are connected to determination circuit 50, and source lines SL0 and SL1 are connected to the ground voltage source.

Determination circuit 50 detects a current value (hereinafter, also referred to as a “first current value”) of current flowing through bit line BL0 connected via column gate transistor YT0 and a current value (hereinafter, also referred to as a “third current value”) of current flowing through bit line BL1 connected via column gate transistor YT1, compares the first current value and the third current value that are detected, and outputs output y. Output y may take on a value of either data 0 or data 1.

More specifically, determination circuit 50 outputs output y of data 0 when the first current value is smaller than the third current value, and outputs output y of data 1 when the first current value is greater than the third current value. Thus, determination circuit 50 determines a magnitude relation between the first current value and the third current value, and outputs output y.

Note that instead of determining the magnitude relation between the first current value and the third current value, determination circuit 50 may detect a current value (hereinafter, also referred to as a “second current value”) of current flowing through source line SL0 and a current value (hereinafter, also referred to as a “fourth current value”) of current flowing through source line SL1, compare the second current value and the fourth current value that are detected, and output output y. This is because current flowing through bit line BL0 (more accurately, column gate transistor YT0) and current flowing through source line SL0 (more accurately, discharge transistor DT0) are the same, and current flowing through bit line BL1 (more accurately, column gate transistor YT1) and current flowing through source line SL1 (more accurately, discharge transistor DT1) are the same.

Thus, determination circuit 50 may determine the magnitude relation between the first or second current value and the third or fourth current value, and output data having the first or second logical value.

When a conversion circuit such as a shunt resistor, which converts the first to fourth current values into voltages, is included in the neural network computation circuit, determination circuit 50 may make similar determinations by using first to fourth voltage values corresponding to the first to fourth current values.

Note that in the computation units in this variation, in order to simplify description, an example in which a positive weight coefficient is included in two memory cells and a negative weight coefficient is included in two memory cells has been described, yet a positive weight coefficient and a negative weight coefficient can each be included in one memory cell to n memory cells, and thus are not limited to be each included in two memory cells. The computation units according to the present disclosure have features that at least one of a positive weight coefficient or a negative weight coefficient is included in two or more memory cells. Furthermore, in this variation, each of the computation units according to the present disclosure may not include both of a positive weight coefficient and a negative weight coefficient, and may include just one weight coefficient (that is, a weight coefficient without a sign) included in at least two memory cells.

### <Conclusion>

As described above, a neural network computing circuit according to the present disclosure obtains a positive weight coefficient or a negative weight coefficient or both the positive and negative weight coefficients using the current values of current flowing through n bits of memory cells, and performs a multiply-accumulate operation of a neural network circuit. Hence, according to storing method 1, an n-time dynamic range can be achieved as compared to a multiply-accumulate operation of a neural network circuit performed using a current value of current flowing through one bit of a memory cell for each of conventional positive and negative weight coefficients, so that performance of a multiply-accumulate operation by the neural network circuit can be enhanced. Furthermore, according to storing method 2, by separately including one weight coefficient using n bits, the current value of current flowing through each bit line can be reduced to one nth, and thus performance of a multiply-accumulate operation by the neural network circuit can be enhanced. Moreover, according to storing method 3, by setting the range of a current value to be written to each of n bits of memory cells, a write algorithm can be changed for each of a current value to be written, and thus reliability of nonvolatile semiconductor storage elements can be improved.

Thus, a neural network computation circuit according to the present embodiment is a neural network computation circuit that holds a plurality of connection weight coefficients in one-to-one correspondence with a plurality of input data items each of which selectively takes on a first logical value or a second logical value, and outputs output data having the first logical value or the second logical value according to a result of a multiply-accumulate operation on the plurality of input data items and the plurality of connection weight coefficients in one-to-one correspondence, the neural network computation circuit including: at least two bits of semiconductor storage elements provided for each of the plurality of connection weight coefficients, the at least two bits of semiconductor storage elements including a first semiconductor storage element and a second semiconductor storage element that are provided for storing the connection weight coefficient. Each of the plurality of connection weight coefficients corresponds to a total current value that is a sum of a current value of current flowing through the first semiconductor storage element and a current value of current flowing through the second semiconductor storage element.

Accordingly, with conventional technology, one connection weight coefficient corresponds to a current value of current flowing through one semiconductor storage element, whereas in the present embodiment, one connection weight coefficient corresponds to a total current value of current flowing through at least two semiconductor storage elements. Thus, one connection weight coefficient is expressed using at least two semiconductor storage elements, and thus the degree of freedom of the connection weight coefficient storing method for the at least two semiconductor storage elements increases, and at least one of improvement in performance of neural network computation or improvement in reliability of a semiconductor storage element that stores therein a connection weight coefficient.

Specifically, with storing method 1, the first semiconductor storage element and the second semiconductor storage element hold a value that satisfies a first condition and a second condition, as a connection weight coefficient included in the plurality of connection weight coefficients. The first condition indicates that the total current value is proportional to a value of the connection weight coefficient, and the second condition indicates that a maximum value of the total current value is greater than a current value of current flowable through the first semiconductor storage element, and is greater than a current value of current flowable through the second semiconductor storage element. Accordingly, as compared with conventional technology, the current value of current flowing through one computation unit corresponding to one connection weight coefficient can be at least doubled (or stated differently, the dynamic range can be increased), and performance of a multiply-accumulate operation in the neural network computation circuit can be increased.

With storing method 2, the first semiconductor storage element and the second semiconductor storage element hold a value that satisfies a third condition and a fourth condition, as a connection weight coefficient included in the plurality of connection weight coefficients. The third condition indicates that the total current value is proportional to a value of the connection weight coefficient, and the fourth condition indicates that the current value of current flowing through the first semiconductor storage element is identical to the current value of current flowing through the second semiconductor storage element. Accordingly, as compared with conventional technology, when the same connection weight coefficient is held, current flowing through one semiconductor storage element can be made one half or less, and thus performance of a multiply-accumulate operation in a neural network computation circuit can be increased.

With storing method 3, the first semiconductor storage element and the second semiconductor storage element hold a value that satisfies a fifth condition and a sixth condition, as a connection weight coefficient included in the plurality of connection weight coefficients. The fifth condition indicates that the current value of current flowing through the first semiconductor storage element is proportional to a value of the connection weight coefficient when the connection weight coefficient is smaller than a predetermined value, and the sixth condition indicates that the current value of current flowing through the second semiconductor storage element is proportional to the value of the connection weight coefficient when the connection weight coefficient is greater than the predetermined value. Accordingly, as compared with conventional technology, a semiconductor storage element to which a connection weight coefficient is to be written is changed to a different one according to the value of the connection weight coefficient, and thus a write algorithm can be changed, so that reliability of the semiconductor storage elements can be improved.

More specifically, a neural network computation circuit according to the present embodiment is a neural network computation circuit that holds a plurality of connection weight coefficients in one-to-one correspondence with a plurality of input data items each of which selectively takes on a first logical value or a second logical value, and outputs output data having the first logical value or the second logical value according to a result of a multiply-accumulate operation on the plurality of input data items and the plurality of connection weight coefficients in one-to-one correspondence, the neural network computation circuit including: a plurality of word lines; a first data line; a second data line; a third data line; a fourth data line; a plurality of computation units in one-to-one correspondence with the plurality of connection weight coefficients, the plurality of computation units each including a first semiconductor storage element and a first cell transistor that are connected in series and a second semiconductor storage element and a second cell transistor that are connected in series, the first semiconductor storage element including one terminal connected to the first data line, the first cell transistor including one terminal connected to the second data line, and a gate connected to a first word line included in the plurality of word lines, the second semiconductor storage element including one terminal connected to the third data line, the second cell transistor including one terminal connected to the fourth data line, and a gate connected to the first word line; a word-line selection circuit that places each of the plurality of word lines in a selected state or a non-selected state; and a determination circuit that outputs data having the first logical value or the second logical value, based on a first total current value or a second total current value, the first total current value being a sum of a current value of current flowing through the first data line and a current value of current flowing through the third data line, the second total current value being a sum of a current value of current flowing through the second data line and a current value of current flowing through the fourth data line. The first semiconductor storage element and the second semiconductor storage element that are included in each of the plurality of computation units hold a corresponding one of the plurality of connection weight coefficients, and the word-line selection circuit places each of the plurality of word lines in the selected state or the non-selected state, according to the plurality of input data items.

Accordingly, each connection weight coefficient can be expressed using two or more semiconductor storage elements aligned in the direction in which bit lines are aligned.

Here, the neural network computation circuit according to the present embodiment may further include: a fifth data line; a sixth data line; a seventh data line; and an eighth data line. The plurality of computation units each may further include: a third semiconductor storage element and a third cell transistor that are connected in series; and a fourth semiconductor storage element and a fourth cell transistor that are connected in series. The third semiconductor storage element may include one terminal connected to the fifth data line. The third cell transistor may include one terminal connected to the sixth data line, and a gate connected to the first word line. The fourth semiconductor storage element may include one terminal connected to the seventh data line. The fourth cell transistor may include one terminal connected to the eighth data line, and a gate connected to the first word line. The determination circuit may determine a magnitude relation between (i) the first total current value or the second total current value and (ii) a third total current value or a fourth total current value, and output data having the first logical value or the second logical value, the third total current value being a sum of a current value of current flowing through the fifth data line and a current value of current flowing through the seventh data line, the fourth total current value being a sum of a current value of current flowing through the sixth data line and a current value of current flowing through the eighth data line. The third semiconductor storage element and the fourth semiconductor storage element that are included in each of the plurality of computation units may hold a corresponding one of the plurality of connection weight coefficients.

At this time, when an input data item included in the plurality of input data items has the first logical value, the word-line selection circuit places a corresponding one of the plurality of word lines in the non-selected state, and when an input data item included in the plurality of input data items has the second logical value, the word-line selection circuit places another corresponding one of the plurality of word lines in the selected state.

Accordingly, the first semiconductor storage element and the second semiconductor storage element can hold a positive-value connection weight coefficient that causes the first total current value or the second total current value to be a current value corresponding to a result of the multiply-accumulate operation on (i) at least two input data items corresponding to at least two connection weight coefficients having positive values and (ii) the at least two connection weight coefficients having the positive values, the at least two input data items being included in the plurality of input data items, the at least two connection weight coefficients being included in the plurality of connection weight coefficients. The third semiconductor storage element and the fourth semiconductor storage element can hold a negative-value connection weight coefficient that causes the third total current value or the fourth total current value to be a current value corresponding to a result of the multiply-accumulate operation on (i) at least two input data items corresponding to at least two connection weight coefficients having negative values and (ii) the at least two connection weight coefficients having the negative values, the at least two input data items being included in the plurality of input data items, the at least two connection weight coefficients being included in the plurality of connection weight coefficients. The positive connection weight coefficient is expressed using at least two semiconductor storage elements aligned in the direction in which bit lines are aligned, and the negative connection weight coefficient is expressed using at least two semiconductor storage elements aligned in the direction in which bit lines are aligned.

The determination circuit outputs: the first logical value when the first total current value is smaller than the third total current value and the second total current value is smaller than the fourth total current value; and the second logical value when the first total current value is greater than the third total current value and the second total current value is greater than the fourth total current value. Accordingly, the determination circuit realizes the step function for determining output of a neuron, according to the sign of the result of the multiply-accumulate operation.

A neural network computation circuit according to this variation is a neural network computation circuit that holds a plurality of connection weight coefficients in one-to-one correspondence with a plurality of input data items each of which selectively takes on a first logical value or a second logical value, and outputs output data having the first logical value or the second logical value according to a result of a multiply-accumulate operation on the plurality of input data items and the plurality of connection weight coefficients in one-to-one correspondence, the neural network computation circuit including: a plurality of word lines; a ninth data line; a tenth data line; a plurality of computation units in one-to-one correspondence with the plurality of connection weight coefficients, the plurality of computation units each including a first semiconductor storage element and a first cell transistor that are connected in series and a second semiconductor storage element and a second cell transistor that are connected in series, the first semiconductor storage element including one terminal connected to the ninth data line, the first cell transistor including one terminal connected to the tenth data line, and a gate connected to a second word line included in the plurality of word lines, the second semiconductor storage element including one terminal connected to the ninth data line, the second cell transistor including one terminal connected to the tenth data line, and a gate connected to a third word line included in the plurality of word lines; a word-line selection circuit that places each of the plurality of word lines in a selected state or a non-selected state; and a determination circuit that outputs data having a first logical value or a second logical value, based on a first current value of current flowing through the ninth data line or a second current value of current flowing through the tenth data line. The first semiconductor storage element and the second semiconductor storage element that are included in each of the plurality of computation units hold a corresponding one of the plurality of connection weight coefficients, and the word-line selection circuit places each of the plurality of word lines in the selected state or the non-selected state, according to the plurality of input data items.

Accordingly, each connection weight coefficient can be expressed using two or more semiconductor storage elements aligned in the direction in which word lines are aligned.

Here, the neural network computation circuit according to the present embodiment may further include: an eleventh data line; and a twelfth data line. The plurality of computation units may each further include: a third semiconductor storage element and a third cell transistor that are connected in series; and a fourth semiconductor storage element and a fourth cell transistor that are connected in series. The third semiconductor storage element may include one terminal connected to the eleventh data line. The third cell transistor may include one terminal connected to the twelfth data line, and a gate connected to the second word line, the fourth semiconductor storage element includes one terminal connected to the eleventh data line. The fourth cell transistor may include one terminal connected to the twelfth data line, and a gate connected to the third word line. The determination circuit may determine a magnitude relation between (i) the first current value or the second current value and (ii) a third current value of current flowing through the eleventh data line or a fourth current value of current flowing through the twelfth data line, and output data having the first logical value or the second logical value. The third semiconductor storage element and the fourth semiconductor storage element that are included in each of the plurality of computation units may hold a corresponding one of the plurality of connection weight coefficients. When an input data item included in the plurality of input data items has the first logical value, the word-line selection circuit places, in the non-selected state, one corresponding word line included in the plurality of word lines, when an input data item included in the plurality of input data items has the second logical value, the word-line selection circuit places, in the selected state, another corresponding word line included in the plurality of word lines, and the one corresponding word line and the other corresponding word line are a set of two word lines that are the second word line and the third word line.

Accordingly, the first semiconductor storage element and the second semiconductor storage element can hold a positive-value connection weight coefficient that causes the first current value or the second current value to be a current value corresponding to a result of the multiply-accumulate operation on (i) at least two input data items corresponding to at least two connection weight coefficients having positive values and (ii) the at least two connection weight coefficients having the positive values, the at least two input data items being included in the plurality of input data items, the at least two connection weight coefficients being included in the plurality of connection weight coefficients. The third semiconductor storage element and the fourth semiconductor storage element can hold a negative-value connection weight coefficient that causes the third current value or the fourth current value to be a current value corresponding to a result of the multiply-accumulate operation on (i) at least two input data items corresponding to at least two connection weight coefficients having negative values and (ii) the at least two connection weight coefficients having the negative values, the at least two input data items being included in the plurality of input data items, the at least two connection weight coefficients being included in the plurality of connection weight coefficients. The positive connection weight coefficient is expressed using at least two semiconductor storage elements aligned in the direction in which word lines are aligned, and the negative connection weight coefficient is expressed using at least two semiconductor storage elements aligned in the direction in which word lines are aligned.

The determination circuit outputs: the first logical value when the first current value is smaller than the third current value or the second current value is smaller than the fourth current value; and the second logical value when the first current value is greater than the third current value or the second current value is greater than the fourth current value. Accordingly, the determination circuit realizes the step function for determining output of a neuron, according to the sign of the result of the multiply-accumulate operation.

The above has described embodiments and variations of the neural network computation circuit according to the present disclosure, yet the neural network computation circuit according to the present disclosure is not limited to the above examples, and is also effective in embodiments resulting from applying various changes, for instance, to the embodiments and variations or other embodiments resulting from combining a portion of the embodiment and variations within a scope that does not depart from the gist of the present disclosure.

For example, a semiconductor storage element included in the neural network computation circuit according to the above embodiment is an example of a variable resistance nonvolatile memory (ReRAM). Yet, to a semiconductor storage element according to the present disclosure, a nonvolatile semiconductor storage element other than the variable resistance memory such as a magnetic variable-resistance nonvolatile storage element (MRAM), a phase-change nonvolatile storage element (PRAM), or a ferroelectric nonvolatile storage element (FeRAM) is also applicable, and a volatile storage element such as DRAM or SRAM is also applicable. Thus, at least one of the first semiconductor storage element or the second semiconductor storage element may be a variable-resistance nonvolatile storage element that includes a variable-resistance element, a magnetic variable-resistance nonvolatile storage element that includes a magnetic variable resistance element, a phase-change nonvolatile storage element that includes a phase-change element, or a ferroelectric nonvolatile storage element that includes a ferroelectric element. Accordingly, a connection weight coefficient is expressed by using a nonvolatile storage element, and is kept being held even in a state in which power is not supplied.

In the neural network computation circuit according to the above embodiment, each connection weight coefficient includes a positive connection weight coefficient included in two memory cells and a negative connection weight coefficient included in two memory cells, but may be one connection weight coefficient without a sign, which is included in two or more memory cells. Alternatively, a positive connection weight coefficient and a negative connection weight coefficient may each be included in three or more memory cells, or only one of a positive connection weight coefficient or a negative connection weight coefficient may be included in two or more memory cells.

Although only some exemplary embodiments of the present disclosure have been described in detail above, those skilled in the art will readily appreciate that many modifications are possible in the exemplary embodiments without materially departing from the novel teachings and advantages of the present disclosure. Accordingly, all such modifications are intended to be included within the scope of the present disclosure.

### INDUSTRIAL APPLICABILITY

A neural network computation circuit according to the present disclosure can improve computation performance and reliability of a neural network computation circuit configured to perform a multiply-accumulate operation using semiconductor storage elements, and thus is useful for mass production of semiconductor integrated circuits that include the neural network computation circuits, and electronic devices that include such circuits.

1. A neural network computation circuit that holds a plurality of connection weight coefficients in one-to-one correspondence with a plurality of input data items each of which selectively takes on a first logical value or a second logical value, and outputs output data having the first logical value or the second logical value according to a result of a multiply-accumulate operation on the plurality of input data items and the plurality of connection weight coefficients in one-to-one correspondence, the neural network computation circuit comprising:
at least two bits of semiconductor storage elements provided for each of the plurality of connection weight coefficients, the at least two bits of semiconductor storage elements including a first semiconductor storage element and a second semiconductor storage element that are provided for storing the connection weight coefficient,
wherein each of the plurality of connection weight coefficients corresponds to a total current value that is a sum of a current value of current flowing through the first semiconductor storage element and a current value of current flowing through the second semiconductor storage element.

2. The neural network computation circuit according to claim 1,
wherein the first semiconductor storage element and the second semiconductor storage element hold a value that satisfies a first condition and a second condition, as a connection weight coefficient included in the plurality of connection weight coefficients,
the first condition indicates that the total current value is proportional to a value of the connection weight coefficient, and
the second condition indicates that a maximum value of the total current value is greater than a current value of current flowable through the first semiconductor storage element, and is greater than a current value of current flowable through the second semiconductor storage element.

3. The neural network computation circuit according to claim 1,
wherein the first semiconductor storage element and the second semiconductor storage element hold a value that satisfies a third condition and a fourth condition, as a connection weight coefficient included in the plurality of connection weight coefficients,
the third condition indicates that the total current value is proportional to a value of the connection weight coefficient, and
the fourth condition indicates that the current value of current flowing through the first semiconductor storage element is identical to the current value of current flowing through the second semiconductor storage element.

4. The neural network computation circuit according to claim 1,
wherein the first semiconductor storage element and the second semiconductor storage element hold a value that satisfies a fifth condition and a sixth condition, as a connection weight coefficient included in the plurality of connection weight coefficients,
the fifth condition indicates that the current value of current flowing through the first semiconductor storage element is proportional to a value of the connection weight coefficient when the connection weight coefficient is smaller than a predetermined value, and
the sixth condition indicates that the current value of current flowing through the second semiconductor storage element is proportional to the value of the connection weight coefficient when the connection weight coefficient is greater than the predetermined value.

5. A neural network computation circuit that holds a plurality of connection weight coefficients in one-to-one correspondence with a plurality of input data items each of which selectively takes on a first logical value or a second logical value, and outputs output data having the first logical value or the second logical value according to a result of a multiply-accumulate operation on the plurality of input data items and the plurality of connection weight coefficients in one-to-one correspondence, the neural network computation circuit comprising:
a plurality of word lines;
a first data line;
a second data line;
a third data line;
a fourth data line;
a plurality of computation units in one-to-one correspondence with the plurality of connection weight coefficients, the plurality of computation units each including a first semiconductor storage element and a first cell transistor that are connected in series and a second semiconductor storage element and a second cell transistor that are connected in series, the first semiconductor storage element including one terminal connected to the first data line, the first cell transistor including one terminal connected to the second data line, and a gate connected to a first word line included in the plurality of word lines, the second semiconductor storage element including one terminal connected to the third data line, the second cell transistor including one terminal connected to the fourth data line, and a gate connected to the first word line;
a word-line selection circuit that places each of the plurality of word lines in a selected state or a non-selected state; and
a determination circuit that outputs data having the first logical value or the second logical value, based on a first total current value or a second total current value, the first total current value being a sum of a current value of current flowing through the first data line and a current value of current flowing through the third data line, the second total current value being a sum of a current value of current flowing through the second data line and a current value of current flowing through the fourth data line,
wherein the first semiconductor storage element and the second semiconductor storage element that are included in each of the plurality of computation units hold a corresponding one of the plurality of connection weight coefficients, and
the word-line selection circuit places each of the plurality of word lines in the selected state or the non-selected state, according to the plurality of input data items.

6. The neural network computation circuit according to claim 5, further comprising:
a fifth data line;
a sixth data line;
a seventh data line; and
an eighth data line,
wherein the plurality of computation units each further include:
a third semiconductor storage element and a third cell transistor that are connected in series; and
a fourth semiconductor storage element and a fourth cell transistor that are connected in series,
the third semiconductor storage element includes one terminal connected to the fifth data line,
the third cell transistor includes one terminal connected to the sixth data line, and a gate connected to the first word line,
the fourth semiconductor storage element includes one terminal connected to the seventh data line,
the fourth cell transistor includes one terminal connected to the eighth data line, and a gate connected to the first word line,
the determination circuit determines a magnitude relation between (i) the first total current value or the second total current value and (ii) a third total current value or a fourth total current value, and outputs data having the first logical value or the second logical value, the third total current value being a sum of a current value of current flowing through the fifth data line and a current value of current flowing through the seventh data line, the fourth total current value being a sum of a current value of current flowing through the sixth data line and a current value of current flowing through the eighth data line, and
the third semiconductor storage element and the fourth semiconductor storage element that are included in each of the plurality of computation units hold a corresponding one of the plurality of connection weight coefficients.

7. The neural network computation circuit according to claim 5,
wherein when an input data item included in the plurality of input data items has the first logical value, the word-line selection circuit places a corresponding one of the plurality of word lines in the non-selected state, and
when an input data item included in the plurality of input data items has the second logical value, the word-line selection circuit places an other corresponding one of the plurality of word lines in the selected state.

8. The neural network computation circuit according to claim 6,
wherein the first semiconductor storage element and the second semiconductor storage element hold a positive-value connection weight coefficient that causes the first total current value or the second total current value to be a current value corresponding to a result of the multiply-accumulate operation on (i) at least two input data items corresponding to at least two connection weight coefficients having positive values and (ii) the at least two connection weight coefficients having the positive values, the at least two input data items being included in the plurality of input data items, the at least two connection weight coefficients being included in the plurality of connection weight coefficients, and
the third semiconductor storage element and the fourth semiconductor storage element hold a negative-value connection weight coefficient that causes the third total current value or the fourth total current value to be a current value corresponding to a result of the multiply-accumulate operation on (i) at least two input data items corresponding to at least two connection weight coefficients having negative values and (ii) the at least two connection weight coefficients having the negative values, the at least two input data items being included in the plurality of input data items, the at least two connection weight coefficients being included in the plurality of connection weight coefficients.

9. The neural network computation circuit according to claim 6,
wherein the determination circuit outputs:
the first logical value when the first total current value is smaller than the third total current value and the second total current value is smaller than the fourth total current value; and
the second logical value when the first total current value is greater than the third total current value and the second total current value is greater than the fourth total current value.

10. A neural network computation circuit that holds a plurality of connection weight coefficients in one-to-one correspondence with a plurality of input data items each of which selectively takes on a first logical value or a second logical value, and outputs output data having the first logical value or the second logical value according to a result of a multiply-accumulate operation on the plurality of input data items and the plurality of connection weight coefficients in one-to-one correspondence, the neural network computation circuit comprising:
a plurality of word lines;
a ninth data line;
a tenth data line;
a plurality of computation units in one-to-one correspondence with the plurality of connection weight coefficients, the plurality of computation units each including a first semiconductor storage element and a first cell transistor that are connected in series and a second semiconductor storage element and a second cell transistor that are connected in series, the first semiconductor storage element including one terminal connected to the ninth data line, the first cell transistor including one terminal connected to the tenth data line, and a gate connected to a second word line included in the plurality of word lines, the second semiconductor storage element including one terminal connected to the ninth data line, the second cell transistor including one terminal connected to the tenth data line, and a gate connected to a third word line included in the plurality of word lines;
a word-line selection circuit that places each of the plurality of word lines in a selected state or a non-selected state; and
a determination circuit that outputs data having a first logical value or a second logical value, based on a first current value of current flowing through the ninth data line or a second current value of current flowing through the tenth data line,
wherein the first semiconductor storage element and the second semiconductor storage element that are included in each of the plurality of computation units hold a corresponding one of the plurality of connection weight coefficients, and
the word-line selection circuit places each of the plurality of word lines in the selected state or the non-selected state, according to the plurality of input data items.

11. The neural network computation circuit according to claim 10, further comprising:
an eleventh data line; and
a twelfth data line,
wherein the plurality of computation units each further include:
a third semiconductor storage element and a third cell transistor that are connected in series; and
a fourth semiconductor storage element and a fourth cell transistor that are connected in series,
the third semiconductor storage element includes one terminal connected to the eleventh data line,
the third cell transistor includes one terminal connected to the twelfth data line, and a gate connected to the second word line,
the fourth semiconductor storage element includes one terminal connected to the eleventh data line,
the fourth cell transistor includes one terminal connected to the twelfth data line, and a gate connected to the third word line,
the determination circuit determines a magnitude relation between (i) the first current value or the second current value and (ii) a third current value of current flowing through the eleventh data line or a fourth current value of current flowing through the twelfth data line, and outputs data having the first logical value or the second logical value, and
the third semiconductor storage element and the fourth semiconductor storage element that are included in each of the plurality of computation units hold a corresponding one of the plurality of connection weight coefficients.

12. The neural network computation circuit according to claim 10,
wherein when an input data item included in the plurality of input data items has the first logical value, the word-line selection circuit places, in the non-selected state, one corresponding word line included in the plurality of word lines,
when an input data item included in the plurality of input data items has the second logical value, the word-line selection circuit places, in the selected state, an other corresponding word line included in the plurality of word lines, and
the one corresponding word line and the other corresponding word line are a set of two word lines that are the second word line and the third word line.

13. The neural network computation circuit according to claim 11,
wherein the first semiconductor storage element and the second semiconductor storage element hold a positive-value connection weight coefficient that causes the first current value or the second current value to be a current value corresponding to a result of the multiply-accumulate operation on (i) at least two input data items corresponding to at least two connection weight coefficients having positive values and (ii) the at least two connection weight coefficients having the positive values, the at least two input data items being included in the plurality of input data items, the at least two connection weight coefficients being included in the plurality of connection weight coefficients, and
the third semiconductor storage element and the fourth semiconductor storage element hold a negative-value connection weight coefficient that causes the third current value or the fourth current value to be a current value corresponding to a result of the multiply-accumulate operation on (i) at least two input data items corresponding to at least two connection weight coefficients having negative values and (ii) the at least two connection weight coefficients having the negative values, the at least two input data items being included in the plurality of input data items, the at least two connection weight coefficients being included in the plurality of connection weight coefficients.

14. The neural network computation circuit according to claim 11,
wherein the determination circuit outputs:
the first logical value when the first current value is smaller than the third current value or the second current value is smaller than the fourth current value; and
the second logical value when the first current value is greater than the third current value or the second current value is greater than the fourth current value.

15. The neural network computation circuit according to claim 1,
wherein at least one of the first semiconductor storage element or the second semiconductor storage element is a variable-resistance nonvolatile storage element that includes a variable-resistance element, a magnetic variable-resistance nonvolatile storage element that includes a magnetic variable resistance element, a phase-change nonvolatile storage element that includes a phase-change element, or a ferroelectric nonvolatile storage element that includes a ferroelectric element.
